(19) United States
(12) Patent Application Publication
(10) Pub. No.: US 2024/0240080 A1
(43) Pub. Date: Jul. 18, 2024

(54) LIGHT-EMITTING MATERIAL AND METHOD FOR PRODUCING THE SAME

(71) Applicant: NICHIA CORPORATION, Anan-shi (JP)

(72) Inventors: Tomokazu YOSHIDA, Anan-shi (JP); Kenichi AOYAGI, Itano-gun (JP); Kazuya NISHIMATA, Anan-shi (JP)

(73) Assignee: NICHIA CORPORATION, Anan-shi (JP)

(21) Appl. No.: 18/565,218

(22) PCT Filed: May 26, 2022
(86) PCT No.: PCT/JP2022/021585

§ 371 Date: Nov. 29, 2023

(30) Foreign Application Priority Data
May 31, 2021 (JP) 2021-091754

(51) Int. Cl. C09K 11/64; C09K 11/02; H01L 33/50

(52) U.S. Cl. CPC C09K 11/646; C09K 11/025; H01L 33/502

(57) ABSTRACT

Provided is a light-emitting material containing a phosphor that emits red light with high luminance. The light-emitting material contains a fluoride phosphor having a first composition containing an alkali metal including K, Si, Al, Mn, and F. In the first composition, when a total number of moles of the alkali metal is 2, a total number of moles of Si, Al, and Mn is in a range from 0.9 to 1.1, a number of moles of Al is in a range from greater than 0 to 0.1, a number of moles of Mn is in a range from greater than 0 to 0.2, and a number of moles of F is in a range from 5.9 to less than 6.0. The fluoride phosphor has a cubic system crystal structure and has a lattice constant of 0.8138 nm or larger.

### TECHNICAL FIELD

The present disclosure relates to a light-emitting material and a method for producing the light-emitting material.

### BACKGROUND ART

Various light-emitting devices in which a light-emitting element and a phosphor are combined have been developed and are being used in a wide range of fields such as in illumination, on-board lighting, displays, and liquid crystal backlights. For example, a phosphor used in a light-emitting device in a liquid crystal backlight application is required to have high color purity, that is, the full width at half maximum of the emission peak must be narrow. For example, JP 2012-224536 A discloses a fluoride phosphor having a composition represented by K₂SiF₆:Mn as a red luminous phosphor having a narrow full width at half maximum of the emission peak.

### SUMMARY OF INVENTION

### Technical Problem

In addition to a narrow full width at half maximum of the emission peak, phosphors used in light-emitting devices are also required to have improved luminance. For example, there is room for improvement in the luminance of the fluoride phosphor disclosed in Patent Document 1. Thus, an object of one aspect of the present disclosure is to provide a light-emitting material containing a phosphor that emits red light with high luminance.

### Solution to Problem

In a first aspect, a light-emitting material contains a fluoride phosphor having a first composition containing an alkali metal including K; Si; Al; Mn; and F. In the first composition, when a total number of moles of the alkali metal is 2, a total number of moles of Si, Al, and Mn is in a range from 0.9 to 1.1, a number of moles of Al is in a range from greater than 0 to 0.1, a number of moles of Mn is in a range from greater than 0 to 0.2, and a number of moles of F is in a range from 5.9 to less than 6.0. The fluoride phosphor has, as the crystal structure, a cubic system crystal structure and has a lattice constant of 0.8138 nm or larger.

In a second aspect, a light-emitting material contains a fluoride phosphor having a first composition containing an alkali metal including K; Si; Al; Mn; and F. In the first composition, when a total number of moles of the alkali metal is 2, a total number of moles of Si, Al, and Mn is in a range from 0.9 to 1.1, a number of moles of Al is in a range from greater than 0 to 0.1, a number of moles of Mn is in a range from greater than 0 to 0.2, and a number of moles of F is in a range from 5.9 to less than 6.0. In an infrared absorption spectrum, the fluoride phosphor has an absorption peak in a wavenumber range of from 590 cm⁻¹ to 610 cm⁻¹.

In a third aspect, a method for producing a light-emitting material includes: preparing first fluoride particles having a second composition containing an alkali metal including K, Si, Mn, and F such that when a total number of moles of the alkali metal is 2, a total number of moles of Si and Mn is in a range from 0.9 to 1.1, a number of moles of Mn is in a range from greater than 0 to 0.2, and a number of moles of F is in a range from 5.5 to less than 6.0; preparing second fluoride particles having a third composition containing an alkali metal including K, Al, and F such that when a number of moles of Al is 1, a total number of moles of the alkali metal is in a range from 2 to 3, and a number of moles of F is in a range from 5 to 6; and subjecting a mixture of the first fluoride particles and the second fluoride particles to a first heat treatment in an inert gas atmosphere at a temperature in a range from 60° C. to 780° C. to produce a first heat-treated material.

### Advantageous Effects of Invention

According to one aspect of the present disclosure, a light-emitting material containing a phosphor that emits red light with high luminance can be provided.

### BRIEF DESCRIPTION OF DRAWINGS

FIG. 1 is a flowchart illustrating an example of the process flow of a method for producing a fluoride phosphor.

FIG. 2 is a schematic cross-sectional view illustrating one example of a light-emitting device containing a fluoride phosphor.

FIG. 3 is a graph illustrating infrared absorption spectra of fluoride phosphors.

FIG. 4 is an example of a scanning electron microscope (SEM) image of a fluoride phosphor according to Comparative Example 1.

FIG. 5 is an example of an SEM image of a fluoride phosphor according to Example 3.

FIG. 6 is a graph illustrating infrared absorption spectra of first and second fluoride particles.

FIG. 7 is an example of a cross-sectional SEM image of a fluoride phosphor according to Example 17.

FIG. 8 is an example of an SEM image of the fluoride phosphor according to Example 17.

### DESCRIPTION OF EMBODIMENTS

The word “step” herein includes not only an independent step, but also a step that cannot be clearly distinguished from another step if the anticipated purpose of the step is achieved. If a plurality of substances applicable to a single component in a composition is present, the content of the single component in the composition means the total amount of the plurality of substances present in the composition, unless otherwise specified. Furthermore, the numeric values of upper and lower limits of numerical ranges described herein can be optionally selected and combined. Note that herein, relationships such as the relationship between a color name and a chromaticity coordinate, the relationship between a wavelength range of light and a color name of monochromatic light are in accordance with JIS Z8110. A full width at half maximum of a light-emitting material, or a light-emitting element means a wavelength width (full width at half maximum: FWHM) of an emission spectrum at which the light emission intensity becomes 50% of the maximum light emission intensity in the emission spectrum. The median size of the phosphor or light-emitting material is the median size based on volume, and refers to the particle size corresponding to a volume accumulation of 50% from the small size side in a particle size distribution based on volume. The particle size distribution of the phosphor or light-emitting material is measured by a laser diffraction method using a laser diffraction particle size distribution measuring device. Furthermore, in the present specification, a plurality of elements described in a formula representing a composition of the first or second light-emitting material and separated by commas (,) means that at least one element among the plurality of elements is contained in the composition. In a formula representing the composition of the phosphor or light-emitting material, the description before a colon (:) indicates a host crystal, and the description following the colon (:) indicates an activating element. Embodiments of the present invention will be described below in detail. The embodiments presented below exemplify fluoride phosphors, light-emitting materials, methods for producing the fluoride phosphors and light-emitting materials, and light-emitting devices that embody the technical concept of the present invention, but the present invention is not limited to the fluoride phosphors, light-emitting materials, methods for producing the fluoride phosphors and light-emitting materials, and light-emitting devices presented below.

### Light-Emitting Material

The light-emitting material contains a fluoride phosphor having a first composition containing a potassium (K)-containing alkali metal, silicon (Si), aluminum (Al), manganese (Mn), and fluoride (F). The fluoride phosphor has a cubic system crystal structure and has a lattice constant of 0.8138 nm or larger. The fluoride phosphor also has an absorption peak in a wavenumber range of from 590 cm⁻¹ to 610 cm⁻¹ in the infrared absorption spectrum. In the first composition, when a total number of moles of the alkali metal is 2, a total number of moles of Si, Al, and Mn is in a range from 0.9 to 1.1, a number of moles of Al is in a range from greater than 0 to 0.1, a number of moles of Mn is in a range from greater than 0 to 0.2, and a number of moles of F is in a range from 5.5 to less than 6.0. The Mn contained in the fluoride phosphor may include tetravalent Mn ions. For example, the fluoride phosphor can be produced by a method for producing a fluoride phosphor which will be described later.

The fluoride phosphor has a composition that contains Si and Al with a specific content ratio of Al, and has a cubic system crystal structure with a lattice constant larger than or equal to a predetermined value, and thereby the fluoride phosphor can exhibit higher luminance. The reason for this can be thought, for example, to be as follows. That is, it is conceivable that substituting some Si atoms constituting the crystal structure of the fluoride phosphor with Al atoms would compensate for the deficiency of F atoms in the crystal structure, thus stabilizing the crystal structure. Substituting some Si atoms in the crystal structure of the fluoride phosphor with Al atoms also makes the lattice constant be equal to or larger than a predetermined value. Furthermore, the fluoride phosphor contains Al in the crystal structure, indicating a peak deriving from an Al—F bond in, for example, the infrared absorption spectrum.

In the first composition of the fluoride phosphor, the ratio of the total number of moles of Si, Al, and Mn to the total number of 2 moles of the alkali metal contained in the composition may be, for example, in a range from 0.9 to 1.1, and preferably in a range from 0.95 to 1.05, or from 0.97 to 1.03, or may be 1.0. The ratio of the number of moles of Al to the total number of 2 moles of the alkali metal may be, for example, in a range from greater than 0 to 0.1, and preferably in a range from greater than 0 to 0.06, greater than 0 to 0.03, from 0.002 to 0.02, or from 0.003 to 0.015. The ratio thereof may also be in a range from 0.005 to 0.06, or from 0.01 to 0.03. The ratio of the number of moles of Mn to the total number of 2 moles of the alkali metal may be, for example, in a range from greater than 0 to 0.2, and preferably in a range from 0.005 to 0.15, from 0.01 to 0.12, or from 0.015 to 0.1. Furthermore, in one aspect, the ratio of the number of moles of F to the total number of 2 moles of the alkali metal may be, for example, in a range from 5.9 to 6.1, and is preferably in a range from 5.9 to 6.1, from 5.92 to 6.05, or from 5.95 to 6.025. Furthermore, in one aspect, the ratio of the number of moles of F to the total number of 2 moles of the alkali metal may be, for example, in a range from 5.5 to less than 6.0, and is preferably in a range from 5.9 to less than 6.0, from 5.96 to 5.995, or from 5.97 to 5.99. In the first composition, the ratio of the number of moles of Si to the total number of 2 moles of the alkali metal may be, for example, in a range from 0.7 to 1.1, and preferably from 0.8 to 1.03, from 0.85 to 1.01, or from 0.92 to less than 0.95. In the first composition, the ratio of the number of moles of Al to the number of moles of Si may be, for example, in a range from 0.001 to 0.14, and preferably from 0.002 to 0.04 or from 0.003 to 0.015. The composition of the fluoride phosphor can be measured, for example, by inductively coupled plasma (ICP) emission spectroscopy.

The first composition of the fluoride phosphor may satisfy the following numerical range. The ratio of the total number of moles of Si, Al, and Mn to the total number of 2 moles of the alkali metal in the composition may be, for example, 0.9 or greater, 0.95 or greater, or 0.97 or greater, and may be 1.1 or less, 1.05 or less, 1.03 or less, or 1.0 or less. The ratio of the number of moles of Al to the total number of 2 moles of the alkali metal may be, for example, greater than 0, 0.002 or greater, 0.003 or greater, 0.005 or greater, or 0.01 or greater, and may be 0.06 or less, 0.03 or less, 0.02 or less, or 0.015 or less. The ratio of the number of moles of Mn to the total number of 2 moles of the alkali metal may be, for example, greater than 0, 0.005 or greater, 0.01 or greater, or 0.015 or greater, and may be 0.2 or less, 0.15 or less, 0.12 or less, or 0.1 or less. In addition, the ratio of the number of moles of F to the total number of 2 moles of the alkali metal may be, for example, 5.5 or greater, 5.9 or greater, 5.92 or greater, 5.95 or greater, or 5.97 or greater, and may be 6.1 or less, 6.05 or less, 6.025 or less, less than 6.0, 5.998 or less, 5.995 or less, or 5.99 or less. In addition, the ratio of the number of moles of Si to the total number of 2 moles of the alkali metal may be, for example, 0.7 or greater, 0.8 or greater, 0.85 or greater, or 0.92 or greater, and may be 1.1 or less, 1.03 or less, 1.01 or less, less than 1, or less than 0.95. The ratio of the number of moles of Al to the number of moles of Si may be, for example, 0.001 or greater, 0.002 or greater, or 0.003 or greater, and may be 0.14 or less, 0.04 or less, or 0.015 or less.

The fluoride phosphor may have, as the first composition, a composition represented by Formula (I).

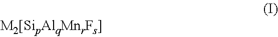

In Formula (I), M represents an alkali metal and may include at least K. Mn may be a tetravalent Mn ion. p, q, r, and s may satisfy 0.9≤p+q+r≤1.1, 0<q≤0.1, 0<r≤0.2, and 5.9≤s≤6.1 or 5.5≤s≤6.0. Preferably, p, q, r, and s satisfy 0.95≤(p+q+r)≤1.05, 0.97≤p+q+r≤1.03 or p+q+r=1.0, 0<q≤0.06, 0<q≤0.03, 0.002≤q≤0.02 or 0.003≤q≤0.015, or 0.005≤q≤0.06 or 0.01≤q≤0.03, 0.005≤r≤0.15, 0.01≤r≤0.12 or 0.015≤r≤0.1, 5.92≤s≤6.05 or 5.95≤s≤6.025, or 5.9≤s<6.0, 5.96≤s≤5.995 or 5.97≤s≤5.99.

In addition, the fluoride phosphor may have a first theoretical composition represented by Formula (Ia).

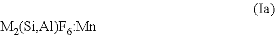

In Formula (Ia), M represents an alkali metal and may include at least K. Mn may be a tetravalent Mn ion.

The alkali metal in the composition of the fluoride phosphor and in the compositions of first fluoride particles and second fluoride particles described later may include at least K, and may include one element selected from the group consisting of lithium (Li), sodium (Na), rubidium (Rb), and cesium (Cs). A ratio of the number of moles of potassium (K) to the total number of moles of the alkali metal in the composition may be, for example, 0.90 or greater, and preferably 0.95 or greater, or 0.97 or greater. The upper limit of the ratio of the number of moles of K may be, for example, not greater than 1 or 0.995. In the first composition, some of the alkali metals may be substituted with ammonium ions (NH₄+). When some of the alkali metals are substituted with ammonium ions, the ratio of the number of moles of the ammonium ions to the total number of moles of the alkali metal in the composition may be, for example, 0.10 or less, and preferably 0.05 or less, or 0.03 or less. The lower limit of the ratio of the number of moles of ammonium ions may be, for example, greater than 0, and may be preferably 0.005 or greater.

The fluoride phosphor may include the cubic system crystal structure, or may include, in addition to the cubic system crystal structure, a crystal structure of another crystal system such as a hexagonal crystal system, or may substantially configured from only the cubic system crystal structure. As used herein, “substantially” means that the content ratio of the crystal structures other than the cubic system crystal structure is less than 0.5%. When the fluoride phosphor includes the cubic system crystal structure, the lattice constant may be, for example, 0.8138 nm or larger, and preferably 0.8140 nm or larger, or 0.8143 nm or larger. The upper limit of the lattice constant may be, for example, 0.8150 nm or less. Evaluation of whether the fluoride phosphor includes the cubic system crystal structure and evaluation of a lattice constant of the cubic system crystal structure can be performed by measuring an X-ray diffraction pattern of the fluoride phosphor. The X-ray diffraction pattern is measured, for example, using CuKα radiation as the X-ray source (λ=0.15418 nm, tube voltage 40 kV, and tube current 40 mA).

The fluoride phosphor may have, for example, an absorption peak in a wavenumber range from 590 cm⁻¹ to 610 cmi, and preferably from 593 cm⁻¹ to 607 cm⁻¹ or from 595 cm⁻¹ to 605 cm⁻¹ in the infrared absorption spectrum. It is conceivable that absorption peak in the predetermined wavenumber range is derived from the Al—F bond in, for example, a cubic system crystal structure. The infrared absorption spectrum is measured by, for example, the attenuated total reflection (ATR) method.

The fluoride phosphor may have irregularities, grooves, or the like in the surface of the particles. It is thought that by taking Al into the crystal structure, the crystal structure of the fluoride phosphor changes, causing irregularities, grooves, or the like to be formed on the surface of particles. The state of the particle surface can be evaluated by, for example, measuring the angle of repose of the powder of fluoride phosphor. The angle of repose of the powder formed from the fluoride phosphor may be, for example, 60° or less, and preferably 55°, or less or 50° or less. The lower limit of the angle of repose is, for example, 30° or higher. The angle of repose of the powder can be measured, for example, using a powder property measuring instrument (for example, A. B. D. Powder Tester from Tsutsui Scientific Instruments Co., Ltd.).

Further, the state of the particle surface of the fluoride phosphor can be evaluated by, for example, measuring the degree of dispersion, the bulk density, or the like of the powder formed from the fluoride phosphor. For a fluoride phosphor having a predetermined degree of dispersion or a predetermined bulk density, aggregation of the powder formed from the fluoride phosphor is suppressed, and thereby handling of the powder is facilitated in producing a light-emitting device, which improves workability in the process of producing the light-emitting device. In addition, the packing density of the fluoride phosphor in the light-emitting device can be increased, and therefore an improvement in luminous flux of the light-emitting device can be anticipated. The degree of dispersion of the powder made of fluoride phosphor may be, for example, 2.0% or greater, and preferably 5.0% or greater, 15% or greater, or 20% or greater. The upper limit of the degree of dispersion may be, for example, 75% or less, 60% or less, or 50% or less. The degree of dispersion of the powder can be measured using, for example, the powder property measuring instrument (for example, A. B. D. Powder Tester from Tsutsui Scientific Instruments, Co., Ltd.). Specifically, the degree of dispersion is calculated in a percentage by dropping a sample from a hopper to a pan for a degree of dispersion and dividing the weight of the dropped sample minus the weight of the sample remaining in the receiving pan by the weight of the dropped sample.

The bulk density of the powder formed from the fluoride phosphor may be, for example, 1.00 g·cm⁻³ or more, and preferably 1.05 g·cm⁻³ or more, 1.10 g·cm⁻³ or more, or 1.15 g·cm⁻³ or more. The upper limit of the bulk density may be, for example, 1.50 g·cm⁻³ or less, 1.40 g·cm⁻³ or less, or 1.30 g·cm⁻³ or less. The bulk density is measured, for example, by a normal measurement method using a measuring cylinder. The bulk density is described specifically. Typically, the bulk density of the powder is determined by measuring the volume of a known weight of the powder sample contained in the measuring cylinder, or by measuring the weight of a known volume of the powder sample put into the container through the Scott Volumeter, or using a dedicated measuring container.

A method for using the measuring cylinder, for example, is described. First, a sufficient amount of sample is prepared for measurement and, if necessary, is passed through a sieve. Subsequently, a required amount of sample is put into a dry and constant volume measuring cylinder. The top surface of the sample is made uniform, if desired. These operations are done statically so as not to affect the physical properties of the sample. The volume is then read to the smallest scale unit, and the bulk density is determined by calculating the weight of the sample per unit volume. The bulk density is preferably measured repeatedly, and is more preferably measured as an arithmetic mean value of the measurement values.

From the perspective of improving luminance, a volume-based median size of the fluoride phosphor may be, for example, in a range from 10 μm to 90 μm, and is preferably in a range from 15 m to 70 μm or from 20 μm to 50 μm. From the perspective of improving luminance, the particle size distribution of the fluoride phosphor may have a single peak, and preferably have a single peak with a narrow distribution range. Specifically, in the volume-based particle size distribution, when the particle size corresponding to 10% cumulative volume from the small size side is D10, and the particle size corresponding to 90% cumulative volume from the small size side is D90, the ratio of D90 to D10 (D90/D10) may be 3.0 or less.

The fluoride phosphor is, for example, a phosphor that is activated by tetravalent Mn, and absorbs light in a short wavelength range of visible light to emit red light. The excitation light may be primarily light in the blue region, and the peak wavelength of the excitation light may be within a wavelength range of, for example, from 380 nm to 485 nm. The emission peak wavelength in the emission spectrum of the fluoride phosphor or light-emitting material may be, for example, within a wavelength range from 610 nm to 650 nm. The full width at half maximum in the emission spectrum of the fluoride phosphor or light-emitting material may be, for example, 10 nm or less.

The light-emitting material may contain a fluoride phosphor and an oxide disposed on at least a portion of a surface of the fluoride phosphor. The oxide may contain at least one element selected from the group consisting of silicon (Si), aluminum (Al), titanium (Ti), zirconium (Zr), tin (Sn), and zinc (Zn). The content percentage of the oxide in the light-emitting material may be in a range from 2 mass % to 30 mass % in relation to the light-emitting material.

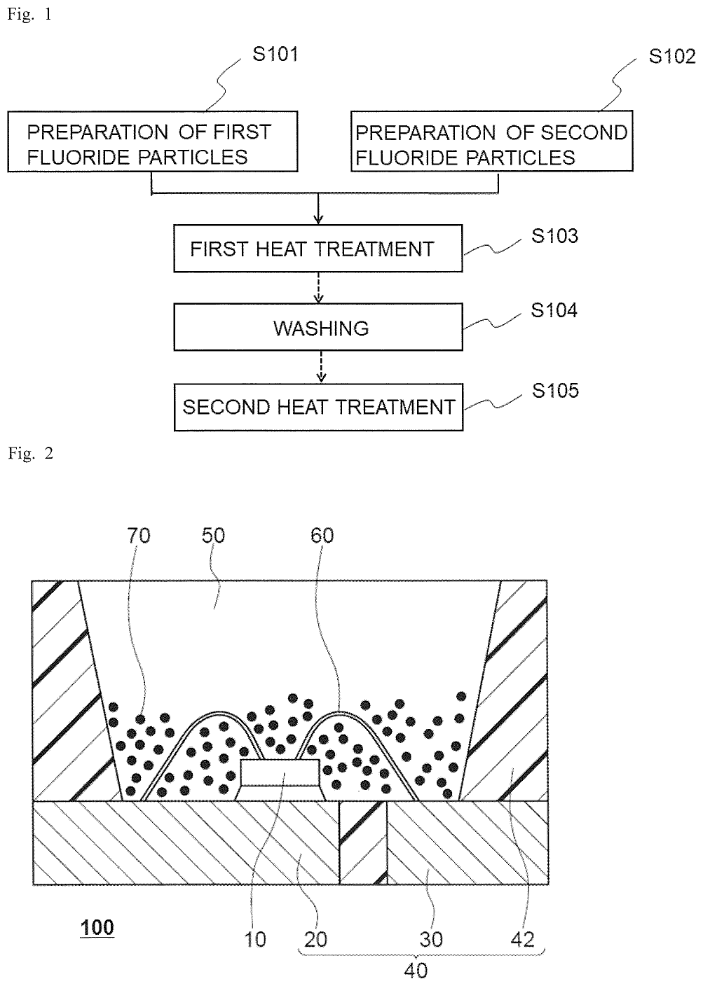

At least a portion of a surface of the fluoride phosphor having a specific composition is covered with a predetermined amount of a specific oxide, and thereby, for example, the moisture resistance of the light-emitting material is improved. Through this, the reliability of a light-emitting device provided with a fluorescent member containing a resin and the light-emitting material containing the fluoride phosphor can be improved. For example, a decrease in the mass of the fluorescent member in a high temperature environment or a high humidity environment is suppressed. The decrease in the mass of the fluorescent member is thought to be mainly a decrease in the amount of the resin. It is conceivable that when the fluoride phosphor and the resin come into direct contact with each other in a high temperature environment or a high humidity environment, some sort of reaction occurs, and a decomposition product in which some interatomic bonds of the resin are broken is scattered. It is also conceivable that when the fluoride phosphor is covered with a predetermined amount of an oxide considered to have higher chemical stability than the fluoride phosphor, direct contact between the resin and the fluoride phosphor is suppressed, and thereby the reaction between the resin and the fluoride phosphor is suppressed, and the amount of the resin is maintained. It is conceivable that since the resin also functions as a protective member for the light-emitting material, a decrease in the amount of the resin makes the light-emitting material more susceptible to the influence of the external environment including moisture and accelerates the deterioration of the light-emitting material. In addition, when the amount of resin decreases, for example, the shape of the light-emitting surface of the fluorescent member in the light-emitting device illustrated in FIG. 1 is deformed, and as a result, the possibility of total reflection of light from the inside of the light-emitting device increases. Therefore, it is conceivable that the amount of light extracted to outside of the light-emitting device decreases, and the luminous flux of the light-emitting device decreases.

The light-emitting material may contain an oxide disposed on at least a portion of the surface of the fluoride phosphor. The oxide may cover the surface of the fluoride phosphor as an oxide film in a film shape, or may be disposed on the surface of the fluoride phosphor in the form of an oxide layer. Furthermore, the oxide film covering the surface of the fluoride phosphor is not limited to a state in which no cracks are present, and cracks may be present in a portion of the oxide film covering the surface of the fluoride phosphor as long as the effect of the present invention can be achieved. In addition, although the oxide film covering the surface of the fluoride phosphor preferably completely covers the entire surface thereof, a portion of the oxide film may be partially missing, and a portion of the surface of the fluoride phosphor may be exposed as long as the effect of the present invention can be achieved. The percentage of the fluoride phosphor covered by the oxide in the light-emitting material may be, for example, 50% or greater, preferably 80% or greater, or 90% or greater. The percentage of the fluoride phosphor covered by the oxide is calculated as the ratio of the surface area covered by the oxide to the surface area of the fluoride phosphor.

The oxide may contain at least one selected from the group consisting of Si, Al, Ti, Zr, Sn, and Zn. That is, the oxide may include at least one selected from the group consisting of silicon oxides (for example, SiOx, where x may be in a range from 1 to 2, preferably from 1.5 to 2, or approximately 2), aluminum oxides (for example, Al₂O₃), titanium oxides (for example, TiO₂), zirconium oxides (for example, ZrO₂), tin oxides (for example, SnO and SnO₂), and zinc oxides (for example, ZnO), and may include at least a silicon oxide. Only a single type of oxide may be included, or two or more types may be included.

The content percentage of the oxide in the light-emitting material may be in a range from 2 mass % to 30 mass %, and is preferably in a range from 5 mass % to 20 mass %, or from 8 mass % to 15 mass %, relative to the light-emitting material. Regarding the content percentage of the oxide in the light-emitting material, when the oxide is silicon oxide for example, the amounts of constituent elements contained in the fluoride phosphor covered by the oxide and in the fluoride phosphor not containing the oxide are analyzed by inductively coupled plasma (ICP) emission spectrometry, and the molar ratios of the respective constituent elements are calculated such that the number of moles of the alkali metal is 2. The difference in the molar ratios of silicon before and after covering with the oxide is converted into the mass of silicon oxide (for example, SiO₂), and the content percentage of the silicon oxide (for example, SiO₂) is calculated with the mass of the fluoride phosphor (light-emitting material) covered with the oxide being 100 mass %. The reliability of the light-emitting device can be further improved by setting the content percentage of the oxide to within the above range.

In the light-emitting material containing a fluoride phosphor, the fluoride phosphor may be covered with an oxide layer. The average thickness of the oxide layer covering the fluoride phosphor may be, for example, in a range from 0.1 μm to 1.8 μm, and preferably in a range from 0.15 μm to 1.0 μm, or from 0.2 μm to 0.8 μm. The average thickness of the oxide layer in the light-emitting material may be, for example, an actually measured average thickness determined by actually measuring the thickness of a layer identified as an oxide layer at several positions in a cross-sectional image of the light-emitting material and calculating the arithmetic mean thereof. The average thickness of the oxide layer in the light-emitting material may be a theoretical thickness calculated from the intensity ratio of Kα rays of F element described below. The theoretical thickness can be calculated from a ratio of a peak intensity of Kα rays of F element in the fluoride phosphor (light-emitting material) covered with an oxide to a peak intensity of Kα rays of F element in the fluoride phosphor not covered with an oxide layer, using a database from The Center for X-Ray Optics (CXRO). The theoretical thickness is calculated as a value calculated by averaging presence of defects such as cracks and chippings in the oxide layer.

In the light-emitting material, since the fluoride phosphor is covered with an oxide, the peak intensity of characteristic X-rays derived from the fluoride phosphor decreases in accordance with the amount of the oxide covering the fluoride phosphor. Therefore, in the light-emitting material containing the fluoride phosphor, the state of coverage by the oxide can be evaluated by evaluating the peak intensity of the characteristic X-rays derived from the fluoride phosphor. Specifically, in X-ray fluorescence (XRF) elemental analysis, the ratio of the peak intensity of Kα rays of the F element in the light-emitting material to the peak intensity of the Kα rays of the F element in the fluoride phosphor may be, for example, 80% or less, and is preferably 70% or less, or 60% or less. The lower limit value of the ratio of the peak intensities may be, for example, 20% or greater. The reliability of the light-emitting device can be more effectively improved by setting the ratio of the peak intensity of the Kα rays of the F element in the light-emitting material to within the above range.

In the light-emitting material, a rare earth phosphate may be disposed on at least a portion of the surface of the fluoride phosphor. This tends to further improve the moisture and heat resistance of the light-emitting material. The rare earth phosphate disposed on the surface of the fluoride phosphor may be adhered as particles to at least a portion of the surface of the fluoride phosphor, or may cover at least a portion of the surface of the fluoride phosphor as a film or a layer. The rare earth phosphate may be preferably adhered as particles to the surface of the fluoride phosphor.

In the light-emitting material, the rare earth phosphate may be disposed on at least a portion of the surface of the fluoride phosphor, and the oxide may cover the fluoride phosphor with the rare earth phosphate interposed therebetween. This tends to further improve the moisture and heat resistance of the light-emitting material. In addition, the adhesiveness of the oxide to the fluoride phosphor is improved, and coatability by the oxide tends to further improve.

The rare earth phosphate may contain at least one rare earth element selected from the group consisting of lanthanum (La), cerium (Ce), dysprosium (Dy) and gadolinium (Gd), and preferably at least lanthanum.

As a content percentage of the rare earth elements, the content percentage of the rare earth phosphate in the light-emitting material may be, for example, in a range from 0.1 mass % to 20 mass %, and preferably in a range from 0.2 mass % to 15 mass %, or from 0.3 mass % to 10 mass %.

The light-emitting material produced by coating the fluoride phosphor with the oxide and/or the rare earth phosphate may have irregularities, grooves, or the like in the surface thereof due to the surface state of the fluoride phosphor, even after being coated with the oxide and/or the rare earth phosphate. As a result, the contact area between the particles of the light-emitting material is reduced due to the irregularities and grooves in the surface of the light-emitting material, and thereby aggregation of the light-emitting material is suppressed. Therefore, the particles of the light-emitting material can be more uniformly dispersed in a resin composition in producing a light-emitting device. In addition, for example, if a dispenser is used in producing a light-emitting device, problems such as the needle of the dispenser becoming clogged with the light-emitting material are less likely to occur. In addition, a light-emitting device in which aggregation of the light-emitting material is minimal and variation in chromaticity is small can be produced.

The surface of the light-emitting material may be further treated with a coupling agent. That is, a surface treatment layer containing a functional group derived from a coupling agent may be disposed on the surface of the light-emitting material. By disposing the surface treatment layer on the surface of the light-emitting material, for example, the moisture resistance of the light-emitting material is further improved.

Examples of the functional group derived from the coupling agent include a silyl group having an aliphatic group with from 1 to 20 carbons, and preferably a silyl group having an aliphatic group with from 6 to 12 carbons. For the functional group derived from the coupling agent, only a single type may be used, or a combination of two or more types may be used.

Examples of the coupling agent include a silane coupling agent, a titanium coupling agent, and an aluminum coupling agent. Examples of the silane coupling agent include alkyl trialkoxysilanes, such as methyl trimethoxysilane, ethyl trimethoxysilane, propyl trimethoxysilane, hexyl trimethoxysilane, octyl trimethoxysilane, decyl trimethoxysilane, and decyl triethylsilane; aryl trialkoxysilanes, such as phenyl trimethoxysilane, and styryl trimethoxysilane; vinyl trialkoxysilanes, such as vinyl trimethoxysilane; aminoalkyl trialkoxysilanes, such as 3-aminopropyl triethoxysilane; and glycidoxyalkyl trialkoxysilanes, such as 3-glycidoxypropyl trimethoxysilane, and the silane coupling agent may be at least one selected from the group consisting of these. From the perspective of being able to relatively easily procure the coupling agent, the coupling agent is preferably a silane coupling agent.

### Method for Producing Light-Emitting Material

FIG. 1 is a flowchart illustrating an example of steps of a method for producing a light-emitting material. The method for producing the light-emitting material may include preparing first fluoride particles (S101), preparing second fluoride particles (S102), and carrying out a first heat treatment to produce a first heat-treated material (S103). Either the preparing of the first fluoride particles (S101) or the preparing of the second fluoride particles (S102) may be done first or both may be done simultaneously. The method for producing the light-emitting material may also include washing (S104) subsequent to the carrying out of the first heat treatment (S103), and may further include, subsequent to the washing (S104), carrying out a second heat treatment to produce a second heat-treated material (S105). The method for producing a light-emitting material may also include, subsequent to the first heat treatment (S103), carrying out a second heat treatment without washing to produce a second heat-treated material (S105).

The method for producing the light-emitting material includes a first preparation step of preparing first fluoride particles, a second preparation step of preparing second fluoride particles, and a first heat treatment step of subjecting a mixture of the first fluoride particles and the second fluoride particles to a first heat treatment in an inert gas atmosphere at a temperature in a range from 600° C. to 780° C. to produce a first heat-treated material. The first fluoride particles have a second composition containing an alkali metal including K, and Si, Mn and F. In the second composition, when the total number of moles of the alkali metal is 2, the total number of moles of Si and Mn is in a range from 0.9 to 1.1, the number of moles of Mn is in a range from greater than 0 to 0.2, and the number of moles of F is in a range from 5.9 to 6.1, or from 5.5 to less than 6.0. The second fluoride particles have a third composition consisting of an alkali metal including K, and Al and F. In the third composition, when the number of moles of Al is 1, the total number of moles of the alkali metal is in a range from 2 to 3, and the number of moles of F is in a range from 5 to 6.

By the heat treatment of the mixture of the first fluoride particles containing Mn as an activating element and the second fluoride particles containing Al at a specific temperature, Al is introduced into the composition of the first fluoride particles, thus providing the fluoride phosphor having high luminance. This is conceivable as follows, for example. That is, it is conceivable that the heat treatment of the mixture of the first and second fluoride particles at a relatively high temperature causes the second fluoride particles to be incorporated into the first fluoride particles and substitutes some of Si atoms in the crystal structure of the first fluoride particles with Al atoms, thus compensating for the deficiency of F atoms in the crystal structure of the fluoride phosphor, stabilizing the crystal structure, and improving luminance.

### First Preparation Step

In the first preparation step, the first fluoride particles having the second composition are prepared. In the second composition, in relation to the total number of 2 moles of the alkali metal, the ratio of the total number of moles of Si and Mn may be in a range from 0.9 to 1.1, the ratio of the number of moles of Mn may be in a range from greater than zero to 0.2, and the ratio of the number of moles of F may be in a range from 5.9 to 6.1, or from 5.5 to less than 6.0. The ratio of the total number of moles of Si and Mn may preferably be in a range from 0.95 to 1.05 or from 0.97 to 1.03. The ratio of the number of moles of Mn may preferably be in a range from 0.005 to 0.15, from 0.01 to 0.12, or from 0.015 to 0.1. Furthermore, the ratio of the number of moles of F may preferably be in a range from 5.95 to 6.05, or from 5.97 to 6.03, or from 5.9 to less than 6.0, from 5.96 to 5.995, or from 5.97 to 5.99.

The first fluoride particles may have the composition represented by Formula (III) as the second composition.

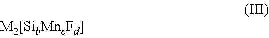

In Formula (III), M represents an alkali metal and may include at least K. Mn may be a tetravalent Mn ion. b, c, and d may satisfy 0.9≤b+c≤1.1, 0<c≤0.2, 5.9≤d≤6.1 or 5.5≤d<6.0. Preferably, b, c, and d satisfy 0.95≤b+c≤1.05 or 0.97≤b+c≤1.03, 0.005≤c≤0.15, 0.01≤c≤0.12 or 0.015≤c≤0.1, 5.95≤d≤6.05 or 5.97≤d≤6.03 or 5.9≤d<6.0, 5.96≤d≤5.995 or 5.97≤d≤5.99.

The first fluoride particles may have a second theoretical composition represented by Formula (IIIa).

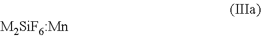

In Formula (IIIa), M represents an alkali metal and may include at least K. Mn may be a tetravalent Mn ion.

From the perspective of improving luminance, the volume-based median size of the first fluoride particles may be, for example, in a range from 10 μm to 90 μm, and preferably in a range from 15 μm to 70 μm or from 20 μm to 50 μm. From the perspective of improving luminance, the particle size distribution of the first fluoride particles may be a particle size distribution having a single peak. Preferably, the particle size distribution may have a single peak with a narrow distribution width. Specifically, in the volume-based particle size distribution, when the particle size corresponding to 10% cumulative volume from the small size side is D10, and the particle size corresponding to 90% cumulative volume from the small size side is D90, the ratio of D90 to D10 (D90/D10) may be 3.0 or less.

The first fluoride particles are made of, for example, the phosphor activated by tetravalent Mn ions, and may absorb light of a short wavelength range of visible light to emit red light. The excitation light may be primarily light in the blue region, and the peak wavelength of the excitation light may be, for example, within a wavelength range of from 380 nm to 485 nm. The emission peak wavelength in the emission spectrum of the first fluoride particles may be, for example, within a wavelength range from 610 nm to 650 nm. The full width at half maximum of the emission spectrum of the first fluoride particles may be, for example, 10 nm or less.

The first fluoride particles may be prepared by purchasing or by producing by a producing method described below. The following describes the production method when the alkali metal is potassium, but the production method can be used similarly even when the alkali metal includes an alkali metal other than potassium.

The method for producing the first fluoride particles includes mixing, for example, a first solution containing at least potassium ions and hydrogen fluoride, a second solution containing at least a first complex ions including tetravalent Mn ions and hydrogen fluoride, and a third solution containing at least second complex ions including silicon and fluorine ions. By mixing the first, second, and third solutions, first fluoride particles having the desired composition and functioning as the phosphor can be produced by a simple and highly productive method.

The first solution contains at least potassium ions and hydrogen fluoride, and may contain other components, as necessary. The first solution is produced, for example, as an aqueous solution of hydrofluoric acid in which a compound containing potassium ions is dissolved. Examples of the compound containing potassium ion constituting the first solution include water soluble compounds such as potassium ion-containing halides, hydrogen fluoride compound, hydroxides, acetates, carbonates, or the like. Specifically, a water soluble potassium salt such as KF, KHF₂, KOH, KCl, KBr, KI, CH₃COOK, K₂CO₃, or the like may be used. In particular, KHF₂ is preferable because it can be dissolved without lowering the hydrogen fluoride concentration in the solution, and has low heat of dissolution and high safety. One type of compound containing potassium ions constituting the first solution may be used alone, or two or more types of compounds may be used in combination.

The lower limit of the hydrogen fluoride concentration in the first solution is typically 1 mass % or greater, preferably 3 mass % or greater, and more preferably 5 mass % or greater. The upper limit of the hydrogen fluoride concentration in the first solution is typically 80 mass % or less, preferably 75 mass % or less, and more preferably 70 mass % or less. The lower limit of the potassium ion concentration in the first solution is typically 1 mass % or greater, preferably 3 mass % or greater, and more preferably 5 mass % or greater. The upper limit of potassium ion concentration in the first solution is typically 30 mass % or less, preferably 25 mass % or less, and more preferably 20 mass % or less. With the potassium ion concentration of 5 mass % or greater, the yield of the first fluoride particle tends to be improved.

The second solution contains at least the first complex ions including tetravalent Mn ions and hydrogen fluoride, and may optionally include other components, as necessary. For example, the second solution is produced as an aqueous solution of hydrofluoric acid containing a tetravalent manganese source. The manganese source is a compound containing the tetravalent Mn ion. Specific examples of the manganese source constituting the second solution include K₂MnF₆, KMnO₄, K₂MnCL₆, or the like. Among these, K₂MnF₆ is preferred because it does not contain chlorine, which tends to distort and destabilize the crystal lattice, and because it can exist stably in hydrofluoric acid as MnF₆ complex ion while maintaining an oxidation number (tetravalent) required for activation. The manganese source containing potassium ions can also function as a source of potassium ions contained in the first solution. One manganese source constituting the second solution may be used alone or two or more manganese sources may be used in combination.

The lower limit of the hydrogen fluoride concentration in the second solution is typically 1 mass % or greater, preferably 3 mass % or greater, and more preferably 5 mass % or greater. The upper limit of the hydrogen fluoride concentration in the second solution is typically 80 mass % or less, preferably 75 mass % or less, and more preferably 70 mass % or less. The lower limit of the first complex ion concentration in the second solution is typically 0.01 mass % or greater, preferably 0.03 mass % or greater, and more preferably 0.05 mass % or greater. The upper limit of the first complex ion concentration in the second solution is typically 5 mass % or less, preferably 3 mass % or less, and more preferably 2 mass % or less.

The third solution contains at least the second complex ions containing silicon and fluorine ions, and may include other components, as necessary. The third solution is produced, for example, as an aqueous solution including a second complex ion source. Preferably, the second complex ion source is a compound containing silicon and fluoride ions, and is excellent in solubility in the solution. Specific examples of the second complex ion source include H₂SiF₆, Na₂SiF₆, (NH₄)₂SiF₆, Rb₂SiF₆, and Cs₂SiF₆. Among these, H₂SiF₆ is preferred due to its high solubility in water and the absence of alkali metal elements as impurities. One second complex ion source constituting the third solution may be used alone or two or more second complex ion sources may be used in combination.

The lower limit of the second complex ion concentration in the third solution is typically 10 mass % or greater, preferably 15 mass % or greater, and more preferably 20 mass % or more. The upper limit of the second complex ion concentration in the third solution is typically 60 mass % or less, preferably 55 mass % or less, and more preferably 50 mass % or less.

To mix the first, second, and third solutions, for example, the second and third solutions may be added to the first solution and mixed while the first solution is stirred, or the first and second solutions may be added to the third solution and mixed while the third solution is stirred. Alternatively, the first, second, and third solutions may be put into a container, respectively, and stirred and mixed.

By mixing the first, second, and third solutions, the first complex ion, the potassium ion, and the second complex ion react to precipitate desired first fluoride particle crystals. The precipitated crystals can be collected by solid-liquid separation by filtration or the like. Alternatively, a reducing agent such as hydrogen peroxide water may be added, or a solvent such as ethanol, isopropyl alcohol, water, acetone, or the like may be used for washing. Drying treatment may further be carried out. The drying treatment may be carried out typically at 50° C. or higher, preferably 55° C. or higher, more preferably 60° C. or higher, and usually 110° C. or lower, preferably 105° C. or lower, more preferably 100° C. or lower. As for the drying time, there is no particular limit, but it is necessary to remove water adhering to the first fluoride particles in, for example, about 10 hours.

When mixing the first, second, and third solutions, it is preferable to adjust the mixing ratio of the first, second, and third solutions appropriately so that the composition of the first fluoride particles as a product becomes the desired composition, taking into consideration the deviation between the prepared composition of the phosphor raw material and the composition of the first fluoride particles produced.

The method for producing the first fluoride particles may include a sizing step in which crushing, grinding, classification operations or the like are carried out in combination subsequent to the drying treatment. The sizing step can provide powder having a desired particle size.

### Second Preparation Step

In the second preparation step, second fluoride particles having a third composition are prepared. In the third composition, in relation to the number of moles of Al of 1, the ratio of the total number of moles of the alkali metal may be in a range from 1 to 3, and the ratio of the number of moles of F may be in a range from 4 to 6. In one aspect of the third composition, in relation to the number of moles of Al of 1, the ratio of the total number of moles of the alkali metal may be in a range from 2 to 3, and the ratio of the number of moles of F may be in a range from 5 to 6.

The second fluoride particles may have a composition represented by Formula (IV) as the third composition.

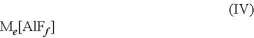

In Formula (IV), M represents an alkali metal and may include at least K. e and f may satisfy 2≤e≤3 and 5≤f≤6.

The second fluoride particles may have a composition represented by Formula (IVa) or (IVb) or may include both compositions.

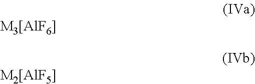

From the perspective of reactivity with the first fluoride particles, the specific surface area of the second fluoride particles is, for example, 0.3 m²·g⁻¹ or greater, and preferably 1 m²·g⁻¹ or greater, or 3 m²·g⁻¹ or greater. The upper limit of the specific surface area of the second fluoride particles may be, for example, 30 m²·g⁻¹ or less. The specific surface area is measured, for example, by the BET method.

The second fluoride particles may be prepared by purchasing or by producing by a known production method.

### First Heat Treatment Step

A first heat treatment step may include mixing the prepared first fluoride particles and second fluoride particles to produce a mixture, and subjecting the produced mixture to a first heat treatment in an inert gas atmosphere at a temperature range from 600° C. to 780° C. to produce a first heat-treated material. The first heat-treated material includes a target fluoride phosphor.

The first and second fluoride particles can be mixed, for example, by dry mixing as is usually done. The dry mixing can be carried out using, for example, a high speed fluid mixer or the like. As the content of the number of moles of the first and second fluoride particles in the mixture, the ratio of the second fluoride particles to the total number of moles of the first and second fluoride particles may be, for example, in a range from greater than 0 to less than 0.1. It is preferably less than 0.05 moles or less than 0.03 moles. The lower limit of the ratio of the number of moles of the second fluoride particles may preferably be 0.003 or greater or 0.005 or greater.

The heat treatment temperature (also referred to as the first heat treatment temperature) in the first heat treatment step may be, for example, 600° C. or higher. Preferably, the heat treatment temperature may be 625° C. or higher, 650° C. or higher, or 675° C. or higher. With the heat treatment temperature is 600° C. or higher, the first fluoride particles can efficiently incorporate the second fluoride particles, allowing some of Si atoms in the crystal structure of the first fluoride particles to be substituted with Al atoms to produce a fluoride phosphor having high luminance. The heat treatment temperature in the first heat treatment step may be, for example, lower than 800° C. Preferably, the heat treatment temperature may be 780° C. or lower, 770° C. or lower, 760° C. or lower, or 750° C. or lower. When the heat treatment temperature is lower than 800° C., thermal decomposition of the fluoride phosphor can be effectively suppressed. In one form, the first heat treatment temperature in the first heat treatment may be in a range from 650° C. to 750° C.

The heat treatment time in the first heat treatment step may be, for example, in a range from 1 hour to 40 hours, preferably from 2 hours to 30 hours. With the heat treatment time in the above range, the substitution of Si atoms with Al atoms in the crystal structure of the first fluoride particles tends to proceed more efficiently, resulting in the fluoride phosphor having higher luminance. As used herein, the heat treatment time in the first heat treatment step means the time to hold the mixture of first and second fluoride particles at the first heat treatment temperature. In the first heat treatment step, a temperature increase rate up to the first heat treatment temperature may be, for example, 1° C./min or greater.

In the first heat treatment step, the heat treatment of the mixture in the inert gas atmosphere may be carried out. The inert gas atmosphere means the atmosphere including, as a main component, an inert gas such as a noble gas, for example, argon, helium, or the like, or nitrogen or the like. The main component in the inert gas atmosphere may be at least one type of element selected from argon, helium, nitrogen, or the like, and may include at least nitrogen. The concentration of the inert gas, for example, nitrogen gas, in the inert gas atmosphere is, 70 vol. % or greater, preferably 80 vol. % or greater, 85 vol. % or greater, 90 vol. % or greater, or 95 vol. % or greater. The inert gas may include an active gas such as oxygen as an unavoidable impurity. The concentration of the active gas contained in the atmosphere in the first heat treatment step needs to be 15 vol. % or less, preferably 5 vol. % or less, 1 vol. % or less, 0.3 vol. % or less, 0.1 vol. % or less. The inert gas atmosphere may be free of active gas such as oxygen. With the concentration of the active gas in the inert gas atmosphere in the above range, the oxidation of tetravalent Mn in the mixture can be sufficiently suppressed.

The pressure during heat treatment in the first heat treatment step may be, for example, atmospheric pressure (0.101 MPa). The pressure during heat treatment may be in a range from higher than 0.101 MPa to 1 MPa, or may be reduced below atmospheric pressure (0.101 MPa).

### Washing Step

The method for producing the light-emitting material may further include a washing step in which the first heat-treated material produced in the first heat treatment step is brought into contact with a first liquid medium. The washing step may include, for example, bringing the first heat-treated material into contact with the first liquid medium and carrying out solid-liquid separation of the first heat-treated material that has been brought into contact with the liquid medium, and as necessary, may further include drying the first heat-treated material after the solid-liquid separation.

For example, at least some impurities (for example, an alkali metal fluoride such as potassium fluoride) produced in the first heat treatment step can be removed by bringing the first heat-treated material into contact with the first liquid medium. This can suppress the change in composition of the fluoride phosphor produced and may effectively suppress the decrease in luminance due to the change in composition.

Examples of the first liquid medium to be brought into contact with the first heat-treated material include lower alcohols such as ethanol and isopropyl alcohol; ketone solvents such as acetone; and water. From the perspective of removing impurities, the first liquid medium may at least contain water, and the water may be deionized water, distilled water, or purified water purified through a microfiltration membrane, an ultrafiltration membrane, a reverse osmosis membrane, or the like.

The first liquid medium may include a reducing agent such as hydrogen peroxide. When the first liquid medium includes the reducing agent, even when the tetravalent Mn ions that function as the activator in the fluoride phosphor are oxidized by the first heat treatment, the oxidized tetravalent Mn ions can be reduced by the reducing agent in the first liquid medium, and the emission characteristic of the resulting fluoride phosphor can be increased. When the first liquid medium contains a reducing agent, the content percentage of the reducing agent may be, for example, in a range from 0.01 mass % to 5 mass %, and preferably from 0.05 mass % to 1 mass %. The amount of the first liquid medium used for contacting the first heat-treated material may be in a range, for example, from 2 times to 20 times the total mass of the first heat-treated material.

The first heat-treated material may be brought into contact with the first liquid medium by mixing the first heat-treated material and the first liquid medium and then removing the first liquid medium, or by causing the first liquid medium to pass through the first heat-treated material held in a funnel or the like. The contact time of the first heat-treated material and the first liquid medium may be, for example, in a range from 1 hour to 20 hours. The contact temperature of the first heat-treated material and the first liquid medium may be, for example, in a range from 10° C. to 50° C.

The first heat-treated material that is in contact with the first liquid medium may be subjected to a drying treatment. A drying temperature during the drying may be, for example, 50° C. or higher, preferably 55° C. or higher, or 60° C. or higher, and may also be, for example, 110° C. or lower, and preferably 105° C. or lower, or 100° C. or lower. The drying time is the time during which at least some of the first liquid medium (for example, moisture) adhering to the first heat-treated material by being in contact with the first liquid medium can be evaporated, and is, for example, about 10 hours.

### Second Heat Treatment Step

The method for producing the light-emitting material may further include a second heat treatment step in which the first heat-treated material subsequent to the contact with the first liquid medium is subjected to a second heat treatment at a second heat treatment temperature of 400° C. or higher to produce a second heat-treated material. The second heat-treated material contains a target fluoride phosphor. The method for producing the light-emitting material may further include a second heat treatment step in which the first heat-treated material not in contact with the liquid medium is subjected to a second heat treatment at a second heat treatment temperature of 400° C. or higher to produce a second heat-treated material.

The action and effect of the second heat treatment step can be considered to be as follows, for example. The fluoride phosphor having the first composition and synthesized by a solid-phase reaction method through the first heat treatment contains a mixture of silicon ions (for example, Si⁴⁺), aluminum ions (for example, Al³⁺), and manganese ions (for example, Mn⁴⁺) at the same atomic coordinates in the crystal, and the atomic coordinates are considered to be in a state of having a mixed valence. Vacancies are thought to be present at the atomic coordinates of the fluorine ions in the crystal according to the abundance ratio of each ion in order to compensate for the deficient charge of cations with mixed valences. Meanwhile, in the fluoride particles having the third composition and synthesized by the liquid phase reaction method, a large number of hydroxide ions introduced into the crystal by the hydroxide ions present in the reaction solution are present in a mixed manner at the atomic coordinates of the fluorine ions in the crystal, and it is conceivable that the hydroxide ions cause a loss of stability of the phosphor. On the other hand, it is conceivable that hydroxide ions that cause a loss of stability of the phosphor are not present in a mixed manner in the fluoride phosphor having the first composition and synthesized by the solid-phase reaction method through the first heat treatment. It is also conceivable that in the fluoride phosphor having the first composition and synthesized by the solid-phase reaction method through the first heat treatment, manganese ions having different valences are present in a mixed manner in the crystals or on the crystal surface of the phosphor. Even in a case in which manganese ions having different valences are present in a mixed manner in the phosphor as described above, the valences of the manganese ions can be uniformly adjusted to a tetravalent state by carrying out the second heat treatment, and it is conceivable that by doing so, the extraction efficiency of fluorescent light emitted from the fluoride phosphor can be increased.

The second heat treatment may be carried out by holding the first heat-treated material at the second heat treatment temperature for a predetermined period of time. The second heat treatment temperature may be, for example, 400° C. or higher, preferably higher than 400° C. such as 425° C. or higher, 450° C. or higher, or 480° C. or higher. The upper limit of the second heat treatment temperature may be, for example, less than 600° C., preferably lower than 580° C. such as 550° C. or lower or 520° C. or lower. The second heat treatment temperature may be a temperature lower than the first heat treatment temperature.

When the second heat treatment temperature is equal to or higher than the lower limit described above, the manganese ions contained in the first heat-treated material can be sufficiently adjusted to a uniform tetravalent state, and the luminance of the resulting light-emitting material containing the fluoride phosphor tends to be further improved. When the second heat treatment temperature is lower than or equal to the upper limit described above, decomposition of the resulting light-emitting material containing the fluoride phosphor is more effectively suppressed, and the luminance of the resulting light-emitting material containing the fluoride phosphor tends to be further improved.

The heat treatment time in the second heat treatment, that is, the time for holding the second heat treatment temperature, may be, for example, in a range from 1 hour to 40 hours, preferably 2 hours or longer or 3 hours or longer, and preferably 30 hours or less, 10 hours or less, or 8 hours or less. When the heat treatment time at the second heat treatment temperature is within the above range, the manganese ions contained in the first heat-treated material can be sufficiently adjusted to a uniform tetravalent state. Through this, the crystal structure of the light-emitting material containing the fluoride phosphor becomes more stable, and a light-emitting material containing the fluoride phosphor with higher luminance tends to be produced.

The heat treatment time at the second heat treatment temperature may be the same as the heat treatment time at the first heat treatment temperature, or may be longer than the heat treatment time at the first heat treatment temperature. That is, the heat treatment time at the second heat treatment temperature may be equal to or longer than the heat treatment time at the first heat treatment temperature. Through this, the manganese ions contained in the first heat-treated material can be sufficiently adjusted to a uniform tetravalent state, and the luminance of the resultant light-emitting material containing the fluoride phosphor tends to be further improved.

The pressure in the second heat treatment step may be atmospheric pressure (0.101 MPa), or may be in a range from greater than atmospheric pressure to 5 MPa or lower, or may be in a range from greater than atmospheric pressure to 1 MPa or lower.

In the second heat treatment step, the second heat treatment may be carried out while the first heat-treated material and the fluorine-containing substance are in contact. The fluorine-containing substance used in the second heat treatment step may be in a solid state, a liquid state, or a gaseous state, at room temperature. An example of a fluorine-containing substance that is in a solid or liquid state is NH₄F. Also, examples of fluorine-containing substances that are in a gaseous state include F₂, CHF₃, CF₄, NH₄HF₂, HF, SiF₄, KrF₄, XeF₂, XeF₄, and NF₃. The fluorine-containing substance that is in a gaseous state may be at least one selected from the group consisting of these, and is preferably at least one selected from the group consisting of F₂ and HE.

The fluorine-containing substance which is in the solid or liquid state at room temperature can be mixed with the first heat-treated material subsequent to the contact with the liquid medium, thus bringing them into contact. For example, the first heat-treated material may be mixed with the fluorine-containing substance in a range from 1 mass % to 20 mass %, and preferably from 2 mass % to 10 mass %, in terms of mass conversion of fluorine atoms, with respect to the total amount of the first heat-treated material and the fluorine-containing substance being 100 mass %.

The temperature at which the first heat-treated material and fluorine-containing substance are mixed may be, for example, in a range from room temperature (20° C.±5° C.) to a temperature lower than the second heat treatment temperature, or may be at the second heat treatment temperature. Specifically, the temperature at which the first heat-treated material and fluorine-containing substance are mixed may be a temperature in a range from 20° C. to lower than 400° C., or may be a temperature of 400° C. or higher. In a case in which the temperature at which the first heat-treated material is brought into contact with the fluorine-containing substance in the solid or liquid state at room temperature is in a range from 20° C. to less than 400° C., the second heat treatment is carried out at a temperature of 400° C. or higher after the first heat-treated material and the fluorine-containing substance are brought into contact.

When the fluorine-containing substance is a gas, the first heat-treated material may be brought into contact with the fluorine-containing substance while being placed in an atmosphere containing the fluorine-containing substance. The atmosphere containing the fluorine-containing substance may contain an inert gas such as noble gas or nitrogen in addition to the fluorine-containing substance. In this case, the concentration of the fluorine-containing substance in the atmosphere may be, for example, in a range from 3 vol. % to 35 vol. %, preferably 5 vol. % or greater or 10 vol. % or greater, and preferably 30 vol. % or less or 25 vol. % or less.

The method for producing the light-emitting material may include a sizing step in which the second heat-treated material produced after the second heat treatment step is subjected to a combination of crushing, grinding, classification operations, and the like. The sizing step can produce a powder having a desired particle size.

In one aspect, the method for producing a light-emitting material may further include a pressurizing and heating step of pressurizing and heating a mixture containing the first heat-treated material and a second liquid medium to produce a third heat-treated material. When the first heat-treated material is subjected to the pressurizing and heating treatment together with the second liquid medium, the luminance of the resultant light-emitting material containing a fluoride phosphor tends to be further improved. Here, the first heat-treated material to be subjected to the pressurizing and heating step may be a product produced after the washing step with the first liquid medium described above.

Examples of the second liquid medium include lower alcohols such as ethanol and isopropyl alcohol; ketone solvents such as acetone; and water. From the perspective of removing impurities, the second liquid medium may at least contain water, and the water may be deionized water, distilled water, or purified water purified through a microfiltration membrane, an ultrafiltration membrane, a reverse osmosis membrane, or the like. The second liquid medium may be a substance that is a gas at normal pressure but is liquefied by pressurization, or a substance that is a solid at normal temperature but is liquefied by heating. For the second liquid medium, only a single type may be used, or two or more types may be combined and used, and as a mass ratio relative to the total mass of the first heat-treated material, the amount of the second liquid medium used in the pressurizing and heating treatment may be, for example, in a range from 0.5 to 2, and preferably in a range from 0.7 to 1.6.

The second liquid medium may further contain a component that is soluble in the second liquid medium. Examples of the component soluble in the second liquid medium include inorganic acids, such as hydrogen fluoride (HF), hexafluorosilicic acid (H₂SiF₆), and nitric acid (HNO₃); peroxides such as hydrogen peroxide; and inorganic acid salts containing potassium ions, such as potassium hydrogen difluoride (KHF₂), potassium nitrate (KNO₃), and potassium fluoride (KF). Of these, the second liquid medium may contain at least potassium ions, and may contain at least an inorganic acid salt containing potassium ions. When the second liquid medium contains potassium ions, the concentration of potassium ions may be, for example, in a range from 5 mass % to 10 mass %. Only a single type of component soluble in the second liquid medium may be used, or two or more types may be used in combination.

From the viewpoint of improving durability of the light-emitting material, the pressure during the pressurization treatment may be, for example, 1.5 MPa or higher, preferably 2.5 MPa or higher, or 5.0 MPa or higher according to calculations. From the viewpoints of durability and production efficiency, the upper limit of the pressure may be, for example, 30 MPa or lower, and preferably 15 MPa or lower.

The time of the pressurization treatment may be appropriately selected according to the treatment conditions such as the pressure. From the viewpoint of improving durability, the treatment time may be, for example, 4 hours or longer, preferably 6 hours or longer, or 8 hours or longer. From the viewpoints of durability and production efficiency, the upper limit of the treatment time may be, for example, 48 hours or less, preferably 24 hours or less, or 20 hours or less.

In the pressurization treatment, for example, the mixture may be inserted into a pressure-resistant airtight container such as an autoclave and pressurized. The pressurizing method may be appropriately selected from commonly used pressurizing methods. Specifically, for example, the pressurization treatment may be carried out by reducing the volume of a pressure-resistant airtight container, by injecting a gas such as air or an inert gas, or by using pressure resulting from the vapor pressure of the liquid medium or the like when the heating treatment is carried out while maintaining an airtight state. The atmosphere in the pressurization treatment may be an air atmosphere or an inert gas atmosphere.

From the viewpoint of improving durability, the temperature of the heating treatment may be, for example, 100° C. or higher, preferably 120° C. or higher, or 150° C. or higher. From the viewpoints of durability and production efficiency, the upper limit of the temperature of the heating treatment may be, for example, 300° C. or lower, and preferably 200° C. or lower.

The time of the heating treatment may be appropriately selected in accordance with treatment conditions such as the temperature. From the viewpoint of durability, the time of the heating treatment may be, for example, 4 hours or longer, and preferably 8 hours or longer. From the viewpoints of durability and production efficiency, the upper limit of the time of the heating treatment may be, for example, 24 hours or less, and preferably 20 hours or less. The atmosphere in the heating treatment may be an air atmosphere or an inert gas atmosphere.

In the method for producing a light-emitting material, when the pressurization and heating treatments are to be carried out, the pressurization treatment and the heating treatment may be implemented sequentially, or each treatment may be carried out in a temporally overlapping manner. When the pressurizing treatment and the heating treatment are implemented in a temporally overlapping manner, for example, the pressurizing treatment can be carried out using the vapor pressure of the liquid medium by inserting the mixture into a pressure-resistant airtight container and then implementing the heating treatment.

In the method for producing a light-emitting material, the first heat-treated material may be subjected to the pressurizing and heating treatments together with a second liquid medium under conditions including, for example, a temperature in a range from 120° C. to 300° C. and a pressure in a range from 2.5 MPa to 30 MPa for a time in a range from 8 hours to 48 hours, and preferably, the pressurizing and heating treatments may be carried out at a temperature in a range from 150° C. to 200° C. and a pressure in a range from 5.0 MPa to 12 MPa for a time in a range from 6 hours to 24 hours.

In addition to the pressurizing treatment and the heating treatment, the method for producing a light-emitting material may further include a post-treatment step such as subjecting a third heat-treatment material to a separation treatment, a purification treatment, or a drying treatment, or may include a sizing step in which treatments such as crushing, grinding, and classification are carried out in combination. A powder having a desired particle size can be produced through the sizing step.

Details of the fluoride phosphor contained in the light-emitting material produced by the method for producing a light-emitting material are the same as those of the above-described fluoride phosphor. That is, the fluoride phosphor contained in the resultant light-emitting material may have a composition represented by Formula (I).

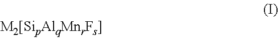

In Formula (I), M represents an alkali metal and may include at least K. Further, p, q, r, and s satisfy 0.9≤p+q+r≤1.1, 0<q<0.1, 0<r<0.2, and 5.9≤s≤6.1 or 5.5≤s<6.0.

The method for producing a light-emitting material may further include a synthesizing step of bringing the first heat-treated material, the second heat-treated material, or the third heat-treated material produced by the above-described production method into contact with, in a liquid medium, a metal alkoxide containing at least one element selected from the group consisting of Si, Al, Ti, Zr, Sn, and Zn to thereby dispose an oxide derived from the metal alkoxide on at least a portion of the surface of the fluoride phosphor contained in the first heat-treated material, the second heat-treated material, or the third heat-treated material. In the synthesizing step, the amount of the oxide to be disposed may be in a range from 2 mass % to 30 mass % in relation to the light-emitting material.

By causing the fluoride phosphor contained in the first heat-treated material, the second heat-treated material or the third heat-treated material, and the metal alkoxide to come into contact in a liquid medium, a light-emitting material in which an oxide derived from the metal alkoxide is disposed on at least a portion of the surface of the fluoride phosphor can be efficiently produced. In a light-emitting device provided with a fluorescent member containing the produced light-emitting material and a resin, reliability in a high temperature environment, for example, is improved.

In the synthesizing step, an oxide derived from the metal alkoxide can be produced by solvolysis of the metal alkoxide, and a light-emitting material is produced in which the produced oxide is disposed on at least a portion of the surface of the fluoride phosphor contained in the second heat-treated material.

An aliphatic group of the alkoxide constituting the metal alkoxide may have a number of carbons, for example, in a range from 1 to 6, preferably from 1 to 4, or from 1 to 3. The oxide may include at least one element selected from the group consisting of Si, Al, Ti, Zr, Sn, and Zn. For each of the metal and the aliphatic group contained in the metal alkoxide, only a single type may be used alone, or two or more types may be used in combination.

Specific examples of the metal alkoxide include tetramethoxy silane, tetraethoxy silane, tetraisopropoxy silane, trimethoxy aluminum, triethoxy aluminum, triisopropoxy aluminum, tetramethoxy titanium, tetraethoxy titanium, tetraisopropoxy titanium, tetramethoxy zirconium, tetraethoxy zirconium, tetraisopropoxy zirconium, tetraethoxy tin, dimethoxy zinc, and diethoxy zinc. The metal alkoxide is preferably at least one selected from the group consisting of these, and is more preferably at least one selected from the group consisting of tetramethoxy silane, tetraethoxy silane, and tetraisopropoxy silane. For metal alkoxide in the synthesizing step, only a single type may be used alone, or two or more types may be used in combination.

As an addition amount in terms of oxide, the addition amount of the metal alkoxide used in the synthesizing step may be, for example, in a range from 2 mass % to 30 mass %, and preferably 5 mass % or greater or 8 mass % or greater, and preferably 25 mass % or less or 20 mass % or less, relative to the total mass of the first heat-treated material, the second heat-treated material, or the third heat-treated material. As an addition amount of metal alkoxide, the addition amount of the metal alkoxide used in the synthesizing step may be, for example, in a range from 5 mass % to 110 mass %, and preferably 15 mass % or greater or 25 mass % or greater, and preferably 90 mass % or less or 75 mass % or less, relative to the total mass of the first heat-treated material, the second heat-treated material, or the third heat-treated material.

Contact between the first heat-treated material, the second heat-treated material, or the third heat-treated material and the metal alkoxide is carried out in a liquid medium. Examples of the liquid medium include water; alcohol-based solvents such as methanol, ethanol, and isopropyl alcohol; nitrile-based solvents such as acetonitrile; and hydrocarbon-based solvents such as hexane. The liquid medium may contain at least water and an alcohol-based solvent. When the liquid medium contains an alcohol-based solvent, the content of the alcohol-based solvent in the liquid medium may be, for example, 60 mass % or greater, and preferably 70 mass % or greater. Furthermore, the content of water in the liquid medium may be, for example, in a range from 4 mass % to 40 mass %.

The liquid medium may further contain a pH adjusting agent. Examples of the pH adjusting agent include an alkaline substance such as ammonia, sodium hydroxide, and potassium hydroxide, and an acidic substance such as hydrochloric acid, nitric acid, sulfuric acid, and acetic acid. When the liquid medium contains a pH adjusting agent, in acidic conditions, the pH of the liquid medium may be, for example, in a range from 1 to 6, and preferably from 2 to 5. In alkaline conditions, the pH of the liquid medium may be in a range from 8 to 12, and preferably from 8 to 11.

The mass ratio of the liquid medium to the first heat-treated material, the second heat-treated material, or the third heat-treated material may be, for example, in a range from 100 mass % to 1000 mass %, preferably 150 mass % or higher or 180 mass % or higher, and preferably 600 mass % or lower or 300 mass % or lower. When the mass ratio of the liquid medium is within the range described above, the fluoride phosphor tends to be more uniformly covered with the oxide.

Contact between the first heat-treated material, the second heat-treated material, or the third heat-treated material and the metal alkoxide can be caused by, for example, adding the metal alkoxide to a suspension containing the first heat-treated material, the second heat-treated material, or the third heat-treated material. As necessary, stirring or the like may be performed at that time. Furthermore, the contact temperature for contact between the first heat-treated material, the second heat-treated material, or the third heat-treated material and the metal alkoxide may be, for example, in a range from 0° C. to 70° C., and preferably from 10° C. to 40° C. The contact time may be, for example, in a range from 1 hour to 12 hours. Note that the time required for addition of the metal alkoxide is also included in the contact time.

The method for producing the light-emitting material may further include, after the synthesizing step, additional steps such as a step of recovering, through solid-liquid separation, the light-emitting material produced in the synthesizing step, and a step of drying the solid-liquid separated light-emitting material.

The method for producing a light-emitting material may further include an adhesion step in which the first heat-treated material, the second heat-treated material, or the third heat-treated material produced by the production method described above, rare earth ions including at least one lanthanoid selected from the group consisting of La, Ce, Dy, and Gd, and phosphate ions are brought into contact in a liquid medium to thereby produce a fluoride phosphor having a rare earth phosphate adhered to at least a portion of the surface of the fluoride phosphor contained in the first heat-treated material, the second heat-treated material, or the third heat-treated material.

By causing the fluoride phosphor contained in the first heat-treated material, the second heat-treated material, or the third heat-treated material to come into contact with rare earth ions and phosphate ions in a liquid medium, a light-emitting material can be efficiently produced with a rare earth phosphate adhered to at least a portion of the surface of the fluoride phosphor. Furthermore, moisture resistance of the light-emitting material having the rare earth phosphate adhered to the surface of the fluoride phosphor tends to be improved.

In the adhesion step, the fluoride phosphor contained in the first heat-treated material, the second heat-treated material, or the third heat-treated material, the rare earth ions, and the phosphate ions are brought into contact with each other in a liquid medium. Through this, the rare earth phosphate is adhered to the surface of the fluoride phosphor, and a fluoride phosphor on which the rare earth phosphate is adhered is produced. It is conceivable that by adhering the rare earth phosphate to the fluoride phosphor in the liquid medium, the rare earth phosphate is, for example, adhered more uniformly to the surface of the fluoride phosphor,

The liquid medium need only be one that can dissolve the phosphate ions and the rare earth ions, and preferably contains at least water from the viewpoint of easily dissolving these ions. As necessary, the liquid medium may further include a reducing agent such as hydrogen peroxide, an organic solvent, a pH adjusting agent, and the like. Examples of the organic solvent that can be contained in the liquid medium include alcohols such as ethanol and isopropanol. Examples of the pH adjusting agent include basic compounds such as ammonia, sodium hydroxide, and potassium hydroxide, and acidic compounds such as hydrochloric acid, nitric acid, sulfuric acid, and acetic acid. When the liquid medium contains a pH adjusting agent, the pH of the liquid medium is, for example, in a range from 1 to 6, and preferably from 1.5 to 4. When the pH is equal to or higher than the lower limit value described above, a sufficient adherence amount of the rare earth phosphate tends to be produced, and when the pH is equal to or less than the upper limit value described above, a decrease in the emission characteristics of the fluoride phosphor tends to be suppressed. When the liquid medium contains water, the content percentage of the water in the liquid medium may be, for example, 70 mass % or greater, 80 mass % or greater, and preferably 90 mass % or greater.

The mass ratio of the liquid medium to the first heat-treated material, the second heat-treated material, or the third heat-treated material is, for example, 100 mass % or greater or 200 mass % or greater and is, for example, 1000 mass % or less or 800 mass % or less. When the mass ratio of the liquid medium is equal to or greater than the above-described lower limit value, more uniform adherence of the rare earth phosphate to the surface of the fluoride phosphor is facilitated, and when the mass ratio of the liquid medium is equal to or less than the above-described upper limit value, the adherence rate of the rare earth phosphate to the fluoride phosphor tends to further improve.

The liquid medium preferably contains phosphate ions, and more preferably contains water and phosphate ions. In a case in which the liquid medium contains phosphate ions, the first heat-treated material, the second heat-treated material, or the third heat-treated material is mixed with the liquid medium, the resultant mixture is then further mixed with a solution containing the rare earth ions, and thereby the phosphate ions and the rare earth ions can be brought into contact with each other in the liquid medium containing the first heat-treated material, the second heat-treated material, or the third heat-treated material. In a case in which the liquid medium contains phosphate ions, the phosphate ion concentration in the liquid medium is, for example, 0.05 mass % or higher, preferably 0.1 mass % or higher, and, for example, 5 mass % or lower, and preferably 3 mass % or lower. When the phosphate ion concentration in the liquid medium is greater than or equal to the lower limit value described above, the amount of the liquid medium does not become excessive, elution of the composition components from the second heat-treated material or the third heat-treated material is suppressed, and the characteristics of the fluoride phosphor contained in the first heat-treated material, the second heat-treated material, or the third heat-treated material tend to be favorably maintained. When the phosphate ion concentration in the liquid medium is less than or equal to the upper limit value described above, uniformity of matter adhered to the first heat-treated material, the second heat-treated material, or the third heat-treated material tends to be favorable.

Phosphate ions include ortho-phosphate ions, polyphosphate (meta-phosphate) ions, phosphite ions, and hypophosphite ions. Polyphosphate ions include polyphosphate ions having a linear structure, such as pyrophosphate ions and tripolyphosphate ions, and cyclic polyphosphate ions, such as hexa-meta-phosphate ions.

In a case in which the liquid medium contains phosphate ions, a compound that serves as a source of phosphate ions may be dissolved in the liquid medium to prepare the liquid medium containing phosphate ions, or a solution containing a phosphate ion source may be mixed with the liquid medium to prepare the liquid medium containing phosphate ions. Examples of the phosphate ion source include: phosphoric acid; meta-phosphoric acid; alkali metal phosphates such as sodium phosphate and potassium phosphate; alkali metal hydrogen phosphates such as sodium hydrogen phosphate and potassium hydrogen phosphate; alkali metal dihydrogen phosphates such as sodium dihydrogen phosphate and potassium dihydrogen phosphate; alkali metal hexa-meta-phosphates such as sodium hexa-meta-phosphate and potassium hexa-meta-phosphate; alkali metal pyrophosphates such as sodium pyrophosphate and potassium pyrophosphate; and ammonium phosphates such as ammonium phosphate.

The liquid medium preferably contains a reducing agent, more preferably contains water and a reducing agent, and even more preferably contains water, phosphate ions, and a reducing agent. When the liquid medium contains a reducing agent, precipitation of manganese dioxide or the like derived from manganese contained in the first heat-treated material, the second heat-treated material, or the third heat-treated material can be effectively suppressed. The reducing agent contained in the liquid medium is preferably one which, for example, can reduce tetravalent manganese ions eluted from the first heat-treated product, the second heat-treated product, or the third heat-treated product into the liquid medium, and examples include hydrogen peroxide, oxalic acid, and hydroxylamine hydrochloride. Of these, hydrogen peroxide decomposes in water and thus does not adversely affect the fluoride phosphor contained in the first heat-treated material, the second heat-treated material, or the third heat-treated material, and therefore hydrogen peroxide is preferable.

In a case in which the liquid medium contains a reducing agent, a compound that serves as a reducing agent may be dissolved in the liquid medium to prepare the liquid medium containing a reducing agent, or a solution containing a reducing agent may be mixed with the liquid medium to prepare the liquid medium containing a reducing agent. The content of the reducing agent in the liquid medium is not particularly limited, but for example, the content may be 0.1 mass % or higher, and preferably 0.3 mass % or higher.

Examples of rare earth elements that become rare earth ions that contact the phosphate ions include, in addition to Sc and Y, lanthanoids including La, Ce, Pr, Nd, Pm, Sm, Eu, Gd, Tb, Dy, Ho, Er, Tm, Yb, and Lu, and the rare earth element is preferably at least one selected from the lanthanoids, and more preferably at least one selected from the group consisting of La, Ce, Dy, and Gd.

Contact between the phosphate ions and the rare earth ions in the liquid medium may be caused, for example by dissolving a compound that serves as a rare earth ion source in a liquid medium containing phosphate ions, or by mixing a liquid medium containing phosphate ions with a solution containing rare earth ions. The solution containing rare earth ions can be prepared, for example, by dissolving a compound that serves as a rare earth ion source in a solvent such as water. The compound that serves as a rare earth ion source is, for example, a metal salt containing a rare earth element, and examples of the anion constituting the metal salt include nitrate ions, sulfate ions, acetate ions, and chloride ions.

Contact between the phosphate ions and the rare earth ions in the liquid medium can include, for example, producing a slurry by mixing the first heat-treated material, the second heat-treated material, or the third heat-treated material with a liquid medium containing phosphate ions and preferably further containing a reducing agent, and then mixing the slurry with a solution containing rare earth ions.

In the liquid medium in which the phosphate ions and the rare earth ions are in contact, the content of the rare earth ions is, for example, 0.05 mass % or greater or 0.1 mass % or greater, and also, for example, 3 mass % or less or 2 mass % or less. Furthermore, the content percentage of the rare earth ions relative to the amount of first heat-treated material, the second heat-treated material, or the third heat-treated material in the liquid medium is, for example, 0.2 mass % or greater or 0.5 mass % or greater, and also, for example, 30 mass % or less or 20 mass % or less. When the concentration of the rare earth ions is greater than or equal to the lower limit described above, the adherence ratio of the rare earth phosphate to the fluoride phosphor tends to further improve, and when the concentration of the rare earth ions is less than or equal to the upper limit described above, the rare earth phosphate tends to be easily and more uniformly adhered to the surface of the fluoride phosphor.

The contact temperature between the rare earth ions and the phosphate ions forming the rare earth phosphate is, for example, in a range from 10° C. to 50° C., and preferably from 20° C. to 35° C. In addition, the contact time is, for example, in a range from 1 minute to 1 hour, and preferably from 3 minutes to 30 minutes. The contact may be caused while stirring of the liquid medium is performed.

After the adhesion step, a separation step may be provided in which the light-emitting material containing the fluoride phosphor to which the rare earth phosphate is adhered is separated from the liquid medium. The separation can be caused by, for example, a solid-liquid separation means such as filtration or centrifugal separation. As necessary, the light-emitting material yielded by solid-liquid separation may also be subjected to a washing treatment, a drying treatment, or the like.

The method for producing a light-emitting material may further include, after the adhesion step, a synthesizing step in which the first heat-treated material, the second heat-treated material, or the third heat-treated material containing the fluoride phosphor to which the rare earth phosphate is adhered is brought into contact with, in a liquid medium, a metal alkoxide containing at least one element selected from the group consisting of Si, Al, Ti, Zr, Sn, and Zn to thereby dispose an oxide derived from the metal alkoxide on at least a portion of the surface of the fluoride phosphor contained in the first heat-treated material, the second heat-treated material, or the third heat-treated material, with the rare earth phosphate being adhered the fluoride phosphor. In the synthesizing step, the amount of the oxide to be disposed may be in a range from 2 mass % to 30 mass % in relation to the light-emitting material. Details of the synthesizing step are as described above.

In the method for producing the light-emitting material, after the rare earth phosphate is adhered to the surface of the fluoride phosphor, the oxide derived from the metal alkoxide is at least partially disposed on the surface of the fluoride phosphor to which the rare earth phosphate is adhered, and thereby the moisture and heat resistance of the resultant light-emitting material tends to be further improved.

The method for producing a light-emitting material may include a surface treatment step in which the fluoride phosphor produced through the first heat treatment step, the second heat treatment step, the pressurizing and heating treatment step, and the synthesizing step or adhesion step is treated with a coupling agent. That is, the method for producing a light-emitting material may include subjecting the fluoride phosphor contained in the first heat-treated material, the second heat-treated material, or the third heat-treated material to a silane coupling treatment. The method for producing a light-emitting material may further include carrying out a silane coupling treatment after the oxide derived from the metal alkoxide has been disposed on at least a portion of the surface of the fluoride phosphor. The method for producing a light-emitting material may further include carrying out a silane coupling treatment after the rare earth phosphate has been disposed on at least a portion of the surface of the fluoride phosphor. The method for producing a light-emitting material may further include carrying out a silane coupling treatment after the rare earth phosphate has been disposed on at least a portion of the surface of the fluoride phosphor and the oxide derived from the metal alkoxide has been disposed on at least a portion of the surface of the fluoride phosphor. In the surface treatment step, the fluoride phosphor and a coupling agent are brought into contact, and thereby a surface treatment layer including a functional group derived from the coupling agent can be provided on the surface of the fluoride phosphor. Through this, for example, moisture resistance of the fluoride phosphor is improved.

Specific examples of the coupling agent used in the surface treatment step are as described above. Moreover, the amount of the coupling agent used in the surface treatment step may be, for example, in a range from 0.5 mass % to 10 mass %, and preferably from 1 mass % to 5 mass %, relative to the mass of the light-emitting material. The contact temperature between the fluoride phosphor and the coupling agent may be, for example, in a range from 0° C. to 70° C., and preferably from 10° C. to 40° C. Furthermore, the contact time between the fluoride phosphor and the coupling agent may be, for example, in a range from 1 minute to 10 hours, and preferably from 10 minutes to 1 hour.

### Light-Emitting Device

The light-emitting device includes a light-emitting material (hereinafter, also referred to as a first light-emitting material) containing the fluoride phosphor, and a light-emitting element having a peak emission wavelength in a wavelength range from 380 nm to 485 nm. The light-emitting device may further include other constituent members as necessary.

An example of the light-emitting device will be described based on the drawings. FIG. 2 is a schematic cross-sectional view illustrating one example of a light-emitting device according to the present embodiment. This light-emitting device is an example of a surface-mounted light-emitting device. The light-emitting device 100 includes a light-emitting element 10 that emits light having a peak emission wavelength on the short-wavelength side of visible light (for example, in a range from 380 nm to 485 nm), and a molded body 40 on which the light-emitting element 10 is mounted. The molded body 40 has a first lead 20 and a second lead 30, and is integrally molded using a thermoplastic resin or a thermosetting resin. A recessed portion having a bottom surface and side surfaces is formed in the molded body 40, and the light-emitting element 10 is placed on the bottom surface of the recessed portion. The light-emitting element 10 includes a pair of positive and negative electrodes, and the pair of the positive and negative electrodes are electrically connected to the first lead 20 and the second lead 30 via wires 60. The light-emitting element 10 is covered by a fluorescent member 50. The fluorescent member 50 includes a wavelength conversion material 70 that converts the wavelength of light from the light-emitting element 10, and the wavelength conversion material includes at least a first light-emitting material. The fluorescent member 50 may contain, as wavelength conversion materials, the first light-emitting material and a second light-emitting material that emits, in response to excitation light from the light-emitting element 10, light having an emission peak wavelength in a wavelength range different from that of the first light-emitting material.

The fluorescent member may contain a resin and a wavelength conversion material. Examples of the resin constituting the fluorescent member include a silicone resin and epoxy resin. The fluorescent member may further contain a light-diffusing material in addition to the resin and wavelength conversion material. Directivity from the light-emitting element can be alleviated, and a viewing angle can be increased by including a light-diffusing material. Examples of the light-diffusing material include silicon oxide, titanium oxide, zinc oxide, zirconium oxide, and aluminum oxide.

The light-emitting element emits light having an emission peak wavelength in a wavelength range from 380 nm to 485 nm, which is a short wavelength range of visible light. The light-emitting element may be an excitation light source that excites a fluoride phosphor. The light-emitting element preferably has an emission peak wavelength within a range from 380 nm to 480 nm, and more preferably has an emission peak wavelength within a range from 410 nm to 480 nm. A semiconductor light-emitting element is preferably used as the light-emitting element of the excitation light source. A semiconductor light-emitting element used as an excitation light source enables a stable light-emitting device that exhibits high efficiency and high output linearity with respect to an input and that is strong against mechanical impact. As the semiconductor light-emitting element, for example, a semiconductor light-emitting element that uses a nitride-based semiconductor can be used. The full width at half maximum of the emission peak in the emission spectrum of the light-emitting element is preferably 30 nm or less, for example.

In the light-emitting device in which the excitation light source is covered with the fluorescent member containing the first light-emitting material, some of the light emitted from the excitation light source is absorbed by the first light-emitting material containing the fluoride phosphor and is emitted as red light. By using an excitation light source that emits light having an emission peak wavelength in the range from 380 nm to 485 nm, the emitted light can be utilized more effectively, loss of light emitted from the light-emitting device can be reduced, and a highly efficient light-emitting device can be provided.

The light-emitting device preferably further includes, in addition to the first light-emitting material containing the fluoride phosphor, a second light-emitting material containing a phosphor other than the fluoride phosphor. The phosphor other than the fluoride phosphor may be any phosphor that absorbs light from the light source and wavelength converts the light into light having a wavelength different from that of the fluoride phosphor. Similar to the first light-emitting material, the second light-emitting material can be contained in the fluorescent member.

The second light-emitting material may have an emission peak wavelength in a range from 495 nm to 590 nm, and may preferably include at least one material selected from the group consisting of β-sialon phosphors, halosilicate phosphors, silicate phosphors, rare earth-aluminate phosphors, perovskite light-emitting materials, and nitride phosphors. The β-sialon phosphor may have a composition represented by Formula (IIa), for example. The halosilicate phosphor may have a composition represented by Formula (IIb), for example. The silicate phosphor may have a composition represented by Formula (IIc), for example. The rare earth-aluminate phosphor may have a composition represented by Formula (IId). The perovskite phosphor may have a composition represented by Formula (IIe), for example. The nitride phosphor may have a composition represented by Formula (IIf), (IIg), or (IIh), for example.

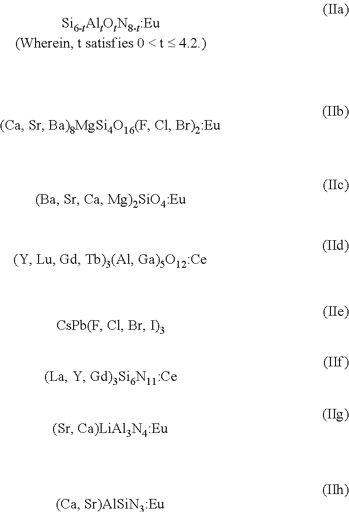

In another aspect, the present invention includes use of a fluoride phosphor having the first composition, having, as a crystal structure, a cubic system crystal structure, and having a lattice constant of 0.8138 nm or larger in the production of the light-emitting material or the light-emitting device. The present invention also includes use of a fluoride phosphor having the first composition and having an absorption peak in a wavenumber range from 590 cm⁻¹ to 610 cm⁻¹ in an infrared absorption spectrum in the production of the light-emitting material or the light-emitting device. The present invention further includes use of the light-emitting material in the production of the light-emitting device.

### EXAMPLES

The present invention will be described in detail below through examples, but the present invention is not limited to these examples.

### Production Example 1: Production of First Fluoride Particles

7029 g of KHF₂ was weighed, and this KHF₂ was dissolved in 68.5 L of a 55 mass % HF aqueous solution to prepare a first solution. Further, 1049.7 g of K₂MnF₆ was weighed, and this K₂MnF₆ was dissolved in 12.0 L of a 55 mass % HF aqueous solution to prepare a second solution. Subsequently, 15.5 L of an aqueous solution containing 40 mass % of H₂SiF₆ was prepared and used as a third solution. The first solution was then stirred at room temperature while the second and third solutions were added dropwise over a period of about 20 hours. After completion of the dropwise addition, 400 mL of a 35% hydrogen peroxide solution were added, washing was implemented with pure water, and the resultant precipitates were subjected to solid-liquid separation and then washed with ethanol and dried at 90° C. for 10 hours, and thereby first fluoride particles of a Production Example 1 were produced. The resultant first fluoride particles had a composition represented by K₂[Si_{0.949}Mn_{0.051}F₆].

### Example 1

2200 g of the first fluoride particles having a composition represented by K₂[Si_{0.949}Mn_{0.051}F₆] produced in Production Example 1 and 7.76 g of the second fluoride particles having a composition represented by K₃[AlF₆] were weighed and mixed such that a ratio of the number of moles of the second fluoride particles to the total number of moles of the first fluoride particles and the second fluoride particles was 0.003, and thereby a mixture of the first fluoride particles and the second fluoride particles was prepared. The mixture of the first fluoride particles and the second fluoride particles was subjected to a first heat treatment in an inert gas atmosphere having a nitrogen gas concentration of 100 vol % at a temperature of 700° C. for a heat treatment time of 5 hours, and thereby a first heat-treated material was produced. The resultant first heat-treated material was sufficiently washed with a washing water containing 1 mass % of hydrogen peroxide. The first heat-treated material after washing was subjected to a second heat treatment at a temperature of 500° C. for a heat treatment time of 5 hours in an atmosphere having a fluorine gas (F₂) concentration of 20 vol % and a nitrogen gas concentration of 80 vol % while the first heat-treated material was in contact with the fluorine gas, and thereby a light-emitting material of Example 1 was produced. Note that the heat treatment time in the first heat treatment and in the second heat treatment is the amount of time that elapses from the time that the predetermined heat treatment temperature is reached to the time at which the heating is stopped. The light-emitting material of Example 1 had a composition represented by K₂[Si_{0.948}Al_{0.002}Mn_{0.050}F_{5.998}].

### Comparative Example 1

A light-emitting material was produced under the same conditions as in Example 1 with the exception that the second fluoride particles were not mixed with the first fluoride particles having the composition represented by K₂[Si_{0.949}Mn_{0.051}F₆] produced in Production Example 1, and only the first fluoride particles were used. The light-emitting material of Comparative Example 1 had a composition represented by K₂[Si_{0.950}Mn_{0.050}F₆].

### Example 2

A light-emitting material was produced under the same conditions as in Example 1 with the exception that the mass of the second fluoride particles was changed to 15.57 g such that the ratio of the number of moles of the second fluoride particles to the total number of moles of the first fluoride particles and the second fluoride particles was 0.006. The light-emitting material of Example 2 had a composition represented by K₂[Si_{0.946}Al_{0.005}Mn_{0.049}F_{5.995}].

### Example 3

A light-emitting material was produced under the same conditions as in Example 1 with the exception that the mass of the second fluoride particles was changed to 23.43 g such that the ratio of the number of moles of the second fluoride particles to the total number of moles of the first fluoride particles and the second fluoride particles was 0.009. The light-emitting material of Example 3 had a composition represented by K₂[Si_{0.942}Al_{0.008}Mn_{0.050}F_{5.992}].

### Example 4

A light-emitting material was produced under the same conditions as in Example 1 with the exception that the mass of the second fluoride particles was changed to 39.28 g such that the ratio of the number of moles of the second fluoride particles to the total number of moles of the first fluoride particles and the second fluoride particles was 0.015. The light-emitting material of Example 4 had a composition represented by K₂[Si_{0.939}Al_{0.014}Mn_{0.047}F_{5.986}].

### Example 5

A light-emitting material was produced under the same conditions as in Example 1 with the exception that the mass of the second fluoride particles was changed to 55.33 g such that the ratio of the number of moles of the second fluoride particles to the total number of moles of the first fluoride particles and the second fluoride particles was 0.021. The light-emitting material of Example 5 had a composition represented by K₂[Si_{0.933}Al_{0.018}Mn_{0.049}F_{5.982}].

### Evaluation

### Chromaticity Coordinates

Using a spectrofluorometer (product name: QE-2000, available from Otsuka Electronics Co., Ltd.), each of the light-emitting materials produced in the Examples and Comparative Examples was irradiated with excitation light having a peak wavelength of 450 nm, and the emission spectrum of each of the light-emitting materials at room temperature was measured. Using the emission spectrum data of each light-emitting material of the Examples and Comparative Examples, the xy chromaticity coordinates in the Commission international de l'eclairage (CIE) 1931 color system were determined. The results are shown in Table 1.

### Relative Luminance

Using the data of the emission spectra measured for the light-emitting materials produced in each of the Examples and Comparative Examples, the emission luminance values of the light-emitting materials of Examples 1 to 5 were determined as relative luminance values with the luminance of the light-emitting material of Comparative Example 1 being 100%. The results are shown in Table 1.

### Composition

The composition of each light-emitting material produced in the Examples and Comparative Examples was analyzed through inductively coupled plasma atomic emission spectrometry (ICP-AES), and the molar content ratio of each element was calculated with the potassium contained in the composition being 2 moles. The results are shown in Table 1.

### Angle of Repose

The angle of repose of each of the light-emitting materials produced in the Examples and Comparative Examples was measured using an A.B.D powder characteristic measuring instrument (product name: ABD-100, available from Tsutsui Scientific Instruments Co., Ltd.), and the angle of repose was determined from the average of two measurements. The results are shown in Table 1.

### Degree of Dispersion

The degree of dispersion of each of the light-emitting materials produced in the Examples and Comparative Examples was measured three times using an A.B.D powder characteristic measuring instrument (product name: ABD-100, available from Tsutsui Scientific Instruments Co., Ltd.), and the arithmetic mean value of the measured values was defined as the degree of dispersion. The results are shown in Table 1.

### Bulk Density

Similar to the degree of dispersion, the bulk density of each of the light-emitting materials produced in the Examples and Comparative Examples was measured three times using the A.B.D powder characteristic measuring instrument (product name: ABD-100, available from Tsutsui Scientific Instruments Co., Ltd.), and the arithmetic mean value of the measured values was defined as the bulk density. The results are shown in Table 1.

### Lattice Constant

Each of the light-emitting materials produced in the Examples and Comparative Examples was mixed with a Si standard sample at a ratio of 1:1, and the X-ray diffraction pattern was measured using a horizontal sample multi-purpose X-ray diffractometer (product name: Ultima IV, available from Rigaku Corporation) and an X-ray source of CuKα rays (λ=0.15418 nm, tube voltage of 40 kV, tube current of 40 mA) under measurement conditions including an angle in a range from 10° to 70°, a scanning width of 0.02°, and a scanning speed of 20°/min. From the X-ray diffraction patterns of the fluoride phosphors produced in Examples 1 to 5 and Comparative Example 1, lattice constants were calculated using integrated powder X-ray analysis software (PDXL2) and card data (K₂SiF₆: 01-081-2264, Si: 00-027-1402) from the International Center for Diffraction Data (ICCD). The results are shown in Table 1.

TABLE 1

| | Chromaticity | | Relative | Mn | Al | Angle of | Degree of | Bulk | Lattice |
|---|---|---|---|---|---|---|---|---|---|
| | coordinates | | luminance | amount | amount | repose | dispersion | density | constant |
| | x | y | (%) | (r) | (q) | (°) | (%) | (g · cm⁻³) | (nm) |
| Comparative | 0.694 | 0.306 | 100.0 | 0.050 | 0.000 | 61 | 1.1 | 0.99 | 0.8137 |
| Example 1 | | | | | | | | | |
| Example 1 | 0.695 | 0.305 | 102.0 | 0.050 | 0.002 | 58 | 2.4 | 1.06 | 0.8139 |
| Example 2 | 0.694 | 0.306 | 103.7 | 0.049 | 0.005 | 55 | 4.2 | 1.08 | 0.8142 |
| Example 3 | 0.694 | 0.306 | 104.0 | 0.050 | 0.008 | 42 | 27.6 | 1.20 | 0.8143 |
| Example 4 | 0.694 | 0.306 | 102.6 | 0.047 | 0.014 | 43 | 32.0 | 1.21 | 0.8150 |
| Example 5 | 0.694 | 0.305 | 101.8 | 0.049 | 0.018 | 41 | 32.6 | 1.23 | 0.8149 |

As shown in Table 1, the light-emitting materials of the Examples exhibited higher luminance than the light-emitting materials of the Comparative Examples. This is presumed to be the effect of reducing the deficiency of F atoms through substitution of some of the Si atoms in the crystal structure with Al atoms in the light-emitting materials of the Examples. Further, in the light-emitting materials of the Examples, the lattice constant increased as the amount of Al was increased. It is thought that this suggests that Si atoms in the crystal structure is substituted with Al atoms.

### Infrared Spectroscopy: FT-IR Evaluation

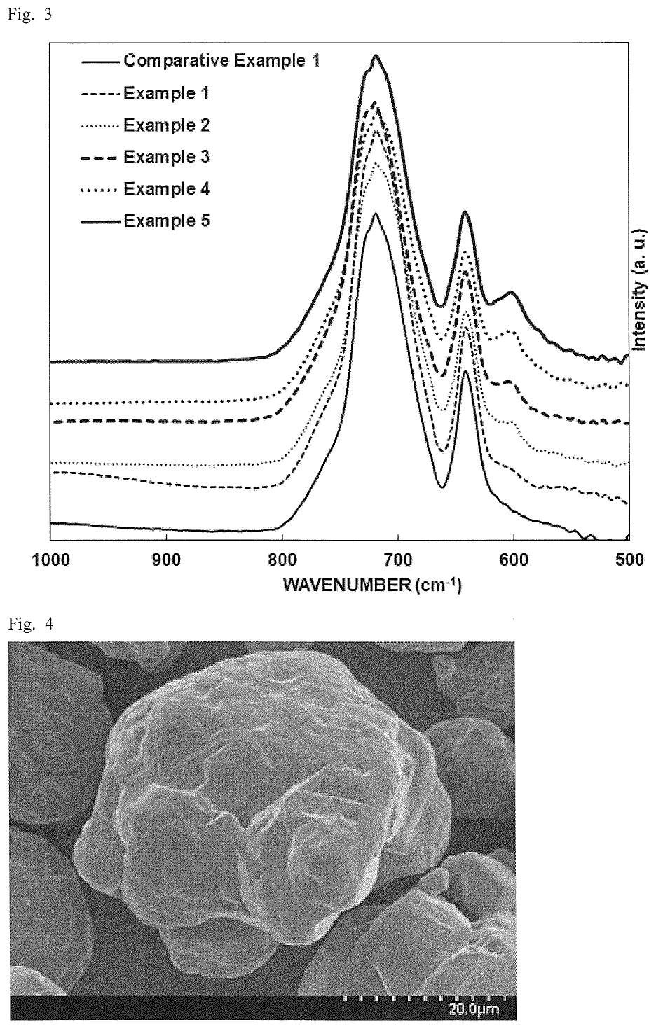

The infrared absorption spectrum of each of the fluoride phosphor light-emitting materials produced in the Examples and Comparative Examples was measured by the attenuated total reflection (ATR) method using a Fourier transform infrared spectrometer (FT-IR-6200, available from JASCO Corporation). FIG. 3 presents an enlarged view of part of the infrared absorption spectra of the light-emitting materials of Examples 1 to 5 and Comparative Example 1. For reference, FIG. 6 presents the infrared absorption spectra of the first fluoride particles and the second fluoride particles.

As illustrated in FIG. 3, the light-emitting materials of the Examples exhibited a characteristic absorption peak in a wavenumber range from 590 cm⁻¹ to 610 cm⁻¹. On the other hand, such an absorption peak was not observed with the light-emitting material of the Comparative Example. This seems to suggest that some of the Si atoms in the crystal structure were substituted with Al atoms in the light-emitting materials of the Examples.

### SEM Image

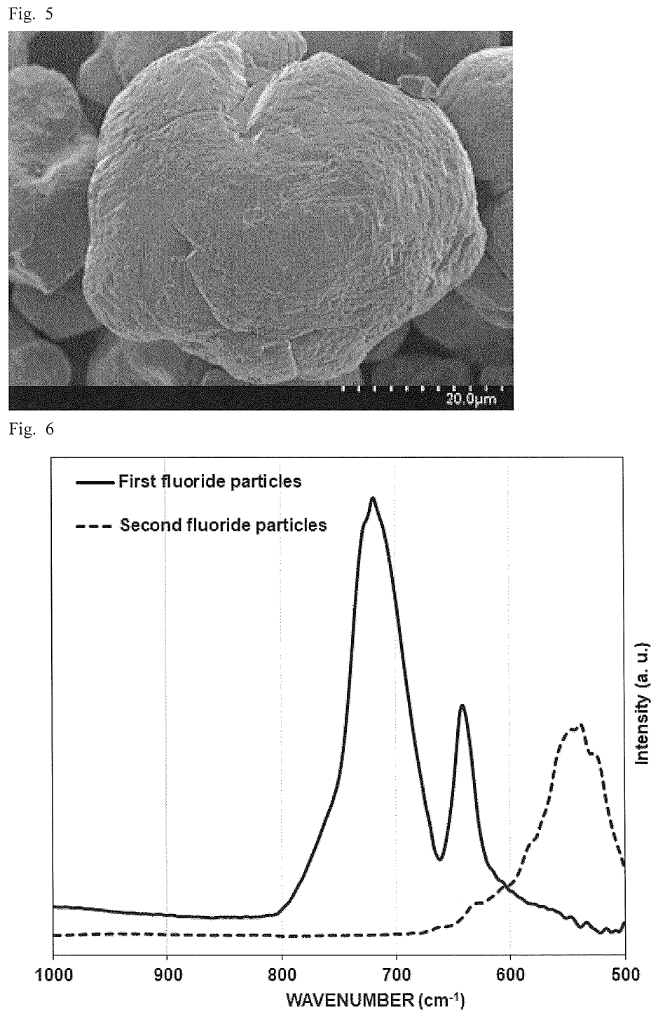

SEM images of the light-emitting materials were taken using a scanning electron microscope (SEM). FIG. 4 illustrates an SEM image of the light-emitting material of Comparative Example 1, and FIG. 5 illustrates an SEM image of the light-emitting material of Example 3.

As compared with the light-emitting material of Comparative Example 1 presented in FIG. 4, the light-emitting material of Example 3 presented in FIG. 5 has fine steps on the particle surface. It is presumed that because of these fine steps, the particles are less likely to aggregate, and therefore the angle of repose is smaller. Due to such a state of the particle surface of the light-emitting material, as shown in Table 1, the degree of dispersion and the bulk density of the light-emitting materials of the Examples were larger than those of the light-emitting material of the Comparative Example, and in the fluoride phosphors of Examples 1 to 5, the degree of dispersion and the bulk density increased as the amount of Al increased.

### Production Example 1 of Light-Emitting Device

Each light-emitting material produced in Example 3 or Comparative Example 1 was used as a first light-emitting material. In addition, a β-sialon phosphor having a composition represented by Si_{5.81}Al_{0.19}O_{0.19}N_{7.81}:Eu and having an emission peak wavelength near 540 nm was used as a second light-emitting material. A resin composition was produced by mixing a silicone resin with a phosphor 70 produced by blending the first light-emitting material and the second light-emitting material such that as the chromaticity coordinates in the CIE1931 color system, x was around 0.280 and y was around 0.270. Subsequently, a molded body 40 having a recessed portion as illustrated in FIG. 2 was prepared, a light-emitting device 10 made of a gallium nitride-based compound semiconductor and having an emission peak wavelength of 451 nm was disposed on the first lead 20 at the bottom of the recessed portion, and then electrodes of the light-emitting device 10 were connected to the first lead 20 and the second lead 30 by respective wires 60. Further, using a syringe, the resin composition was injected into the recessed portion of the molded body 40 so as to cover the light-emitting element 10, and the resin composition was cured to form a fluorescent member, and thereby a light-emitting device 1 was produced.

### Relative Luminous Flux

The luminous flux of the light-emitting device 1 in which the light-emitting material of Example 3 was used, and the luminous flux of the light-emitting device 1 in which the light-emitting material of Comparative Example 1 was used were measured using a total luminous flux measuring device in which an integrating sphere was used. The luminous flux of the light-emitting device 1 that used the light-emitting material of Example 3 was determined as a relative luminous flux with the luminous flux of the light-emitting device 1 that used the fluoride phosphor according to Comparative Example 1 being 100%. The results are shown in Table 2.

TABLE 2

| | | Mass (%) of | Light-emitting | | | | |
|---|---|---|---|---|---|---|---|
| Light-emitting material | | light-emitting | material mass ratio(%) | | | | |
| Second light- | First light- | material per | Second light- | First light- | Chromaticity | | Relative |
| emitting | emitting | 100 parts by | emitting | emitting | coordinates | | luminous |
| material | material | mass of resin | material | material | x | y | flux (%) |
| β-sialon | Comparative | 34.0 | 38.1 | 61.9 | 0.280 | 0.270 | 100.0 |
| | Example 1 | | | | | | |
| β-sialon | Example 3 | 34.6 | 38.3 | 61.7 | 0.280 | 0.270 | 100.5 |

As shown in Table 2, in comparison to the light-emitting device that used the light-emitting material of Comparative Example 1, the relative luminous flux of the light-emitting device that used the light-emitting material of Example 3 was improved by using a light-emitting material having high emission luminance.

### Comparative Example 2

A light-emitting material of Comparative Example 2 having a second theoretical composition represented by K₂SiF₆:Mn (hereinafter, may be abbreviated as “KSF”) with an Mn content percentage of 1.5 mass % was produced by the same method as Production Example 1.

### Comparative Example 3

The fluoride phosphor produced in Comparative Example 2 was subjected to a second heat treatment at a temperature of 500° C. for 8 hours while being in contact with fluorine gas in an atmosphere having a fluorine gas (F₂) concentration of 20 vol % and a nitrogen gas concentration of 80 vol %, and thereby a light-emitting material of Comparative Example 3 having a second theoretical composition represented by K₂SiF₆:Mn with a Mn content percentage of 1.5 mass % was produced.

### Example 6

Through the same method as in Production Example 1, first fluoride particles were produced as a phosphor having a second theoretical composition represented by K₂SiF₆:Mn with a Mn content percentage of 1.1 mass %. A mixture was prepared by weighing and mixing the produced first fluoride particles and second fluoride particles having a composition represented by K₃[AlF₆] such that the ratio of the number of moles of the second fluoride particles to the total number of moles of the first fluoride particles and the second fluoride particles was 0.01. The mixture was subjected to a first heat treatment in an inert gas atmosphere having a nitrogen gas concentration of 100 vol % at a temperature of 700° C. for a heat treatment time of 5 hours, and a first heat-treated material was produced. The resultant first heat-treated material was thoroughly washed with washing water containing 1 mass % of hydrogen peroxide, and thereby a light-emitting material of Example 6 was produced as a fluoride phosphor having a first theoretical composition represented by K₂Si_{0.99}Al_{0.01}F_{5.99}:Mn with an Mn content percentage of 1.1 mass %.

### Example 7

6.7 g of KHF₂ was dissolved in 33.3 g of a 55% hydrofluoric acid aqueous solution to prepare liquid medium 1. The liquid medium 1 and 50 g of the fluoride phosphor produced in Example 6 were placed in a fluorine resin-coated autoclave, and heated and pressurized at 170° C. and approximately 7.5 MPa for 8 hours. The resultant heated and pressurized product was sufficiently washed with washing water containing 1 mass % of hydrogen peroxide, subjected to solid-liquid separation, and then washed with ethanol and dried at 90° C. for 10 hours, and thereby a light-emitting material of Example 7 was produced.

### Example 8

Through the same method as described above, first fluoride particles having a second theoretical composition represented by K₂SiF₆:Mn with a Mn content percentage of 1.1 mass % were produced. The first heat treatment and washing were carried out by the same methods as those of Example 6 with the exception of using the resultant first fluoride particles, and thereby fluoride particles were produced as a phosphor having the first theoretical composition.

Subsequently, the resultant fluoride particles, which were the phosphor having the first theoretical composition, were subjected to a second heat treatment at a temperature of 500° C. for 8 hours in an atmosphere having a fluorine gas (F₂) concentration of 20 vol % and a nitrogen gas concentration of 80 vol % while being in contact with fluorine gas, and thereby a light-emitting material of Example 8 was produced as a fluoride phosphor having the first theoretical composition represented by K₂Si_{0.99}Al_{0.01}F_{5.99}:Mn with a Mn content percentage of 1.0 mass %.

### Example 9

Through the same method as described above, first fluoride particles having a second theoretical composition represented by K₂SiF₆:Mn with a Mn content percentage of 1.6 mass % were produced. The first heat treatment, washing, and the second heat treatment were carried out in the same manner as in Example 8 with the exception that the resultant first fluoride particles were used, and thereby a light-emitting material of Example 9 was produced as a fluoride phosphor having the first theoretical composition represented by K₂Si_{0.99}Al_{0.01}F_{5.99}:Mn with a Mn content percentage of 1.5 mass %.

### Example 10

15.0 g of 35 mass % hydrogen peroxide and 735.0 g of pure water were added to 150.0 g of an aqueous sodium salt solution of phosphoric acid (phosphoric acid concentration: 2.4 mass %), and while the mixture was stirred (with stirring blades at a rotational speed of 400 rpm) at room temperature, 300 g of the fluoride phosphor produced in Example 9 were added thereto, and a phosphor was thereby prepared.

Subsequently, a lanthanum nitrate aqueous solution (lanthanum concentration: 5.0 mass %) prepared by dissolving 23.4 g of lanthanum nitrate dihydrate in 156.6 g of pure water was added dropwise to the phosphor slurry over approximately 1 minute. Stirring was stopped approximately 30 minutes after the dropwise addition was completed, and the mixture was allowed to stand. Subsequently, the supernatant was removed, after which the precipitate was sufficiently washed with washing water containing 1 mass % of hydrogen peroxide. The resultant precipitate was subjected to solid-liquid separation, and then washed with ethanol, and dried at 90° C. for 10 hours, and thereby a light-emitting material having lanthanum phosphate disposed on the surface was prepared as Example 10.

### Example 11

A light-emitting material of Example 11 in which lanthanum phosphate was disposed on the surface was produced by the same method as in Example 10 with the exception that the fluoride phosphor produced in Example 8 was used.

### Example 12

Through the same method as described above, first fluoride particles having a second theoretical composition represented by K₂SiF₆:Mn with a Mn content percentage of 1.3 mass % were produced. The first heat treatment, washing, and the second heat treatment were carried out in the same manner as in Example 8 with the exception that the resultant first fluoride particles were used, and thereby a fluoride phosphor that is a phosphor having the first theoretical composition represented by K₂Si_{0.99}Al_{0.01}F_{5.99}:Mn with a Mn content of 1.2 mass % was produced. A light-emitting material of Example 12 in which lanthanum phosphate was disposed on the surface was produced by the same method as in Example 10 with the exception that the resultant fluoride phosphor having the first theoretical composition was used.

### Comparative Example 4

A light-emitting material of Comparative Example 4 in which lanthanum phosphate was disposed on the surface was produced by the same method as in Example 10 with the exception that the fluoride phosphor produced in Comparative Example 3 was used.

### Example 13

100 g of the fluoride phosphor produced in Example 6 was weighed and added to a mixed solution of 180 mL of ethanol, 43.4 mL of ammonia water containing 16.5 mass % of ammonia, and 20 mL of pure water, and the liquid temperature was maintained at room temperature while the solution was stirred with a stirring blade at 300 rpm, and a reaction mother liquid was thereby produced. 35.7 g of tetraethoxysilane (TEOS: Si(OC₂H₅)₄) was weighed and added dropwise over a period of approximately 3 hours to the reaction mother liquid under stirring. Subsequently, stirring was continued for 1 hour, and 10 g of 35 mass % hydrogen peroxide (H₂O₂) were further added, after which the stirring was stopped. The resultant precipitate was subjected to solid-liquid separation, and then washed with ethanol and dried at 105° C. for 10 hours, and thereby a light-emitting material covered with silicon dioxide (SiO₂) was prepared as Example 13. The amount of tetraethoxysilane added dropwise was approximately 10 mass % in terms of the silicon dioxide relative to the fluoride particles.

### Example 14

A light-emitting material of Example 14 was produced by the same method as in Example 13 with the exception that the fluoride phosphor produced in Example 7 was used.

### Example 15

A light-emitting material of Example 15 was prepared by the same method as Example 13 with the exception that 300 g of the fluoride phosphor produced in Example 8 was weighed and added to a mixed solution of 540 mL of ethanol, 130.2 mL of ammonia water containing 16.5 mass % of ammonia, and 60 mL of pure water, and the liquid temperature was maintained at room temperature while the solution was stirred with a stirring blade at 350 rpm, and a reaction mother liquid was thereby produced, the dropwise addition amount of tetraethoxysilane (TEOS: Si(OC₂H₅)₄) was 107.1 g, and the time for dropwise addition of the tetraethoxysilane was 6 hours. The amount of tetraethoxysilane added dropwise was approximately 10 mass % in terms of the silicon dioxide relative to the fluoride particles.

### Example 16

A light-emitting material of Example 16 was produced by the same method as in Example 15 with the exception that the fluoride phosphor produced in Example 9 was used, and the stirring speed was 500 rpm.

### Example 17

A light-emitting material of Example 17 was produced by the same method as in Example 16 with the exception that the fluoride phosphor produced in Example 10 was used.

### Example 18

50 g of the light-emitting material prepared in Example 17 was weighed. Subsequently, 84.9 mL of ethanol, 5.8 mL of pure water, and decyltrimethoxysilane ((CH₃O)₃Si(CH₂)₉CH₃) as a silane coupling agent were mixed and stirred for 30 minutes, after which the solution was allowed to stand for 20 hours or longer. The fluoride phosphor E10 prepared in Example 10 was added to the solution, and the mixture was stirred at 200 rpm for 1 hour, after which the stirring was stopped. The resultant precipitate was subjected to solid-liquid separation and then dried at 105° C. for 10 hours to carry out a silane coupling treatment, and thereby a light-emitting material of Example 18 was produced.

### Example 19

A light-emitting material of Example 19 was produced by the same method as in Example 15 with the exception that the dropwise addition amount of tetraethoxysilane was 64.3 g.

### Example 20

A light-emitting material of Example 20 was produced by the same method as in Example 15 with the exception that the dropwise addition amount of tetraethoxysilane was 32.2 g.

### Example 21

A fluoride phosphor E16 of Example 21 was produced by the same method as in Example 15 with the exception that the light-emitting material produced in Example 11 was used.

### Example 22

A light-emitting material of Example 22 was produced by the same method as in Example 18 with the except that the light-emitting material produced in Example 21 was used.

### Example 23

A light-emitting material was produced by the same method as in Example 19 with the exception that the light-emitting material produced in Example 12 was used. The resultant light-emitting material was subjected to a silane coupling treatment by the same method as in Example 18 with the exception that hexyltrimethoxysilane was used as the silane coupling agent, and thereby a light-emitting material of Example 23 was produced.

### Example 24

A light-emitting material of Example 24 was produced by the same method as in Example 23 with the exception that vinyltrimethoxysilane was used as the silane coupling agent.

### Example 25

A light-emitting material of Example 25 was produced by the same method as in Example 23 with the exception that 3-aminopropyl triethoxysilane was used as the silane coupling agent.

### Example 26

A light-emitting material of Example 26 was produced by the same method as in Example 23 with the exception that 3-glycidoxypropyl trimethoxysilane was used as the silane coupling agent.

### Evaluation

### (1) Infrared Spectroscopy: FT-IR Evaluation

Infrared absorption spectra of the light-emitting materials produced in Example 6 and Comparative Examples 2 and 3 were measured by a diffuse reflection method using the Fourier transform infrared spectrometer iS (available from Thermo Fisher Scientific Inc.) with a KBr background. Corrections were implemented using the value at 4000 cm⁻¹ as a baseline, a Kubelka-Munk transformation was implemented, and the maximum peak was normalized to measure the absorption spectrum.

Attention was focused on peak components in wavenumber ranges from 1050 cm⁻¹ to 1350 cm⁻¹ and from 3500 cm⁻¹ to 3800 cm⁻¹ of the measured absorption spectrum, and the integral areas (IR peak areas) of the peaks were respectively determined. Further, an IR peak area ratio Z1 was determined as an area ratio represented by Equation (P). Note that the peak area of the range from 3500 cm⁻¹ to 3800 cm⁻¹ was determined using a straight line connecting the intensity at 3000 cm⁻¹ and the intensity at 3800 cm⁻¹ as a background, and the peak area of the range from 1050 cm⁻¹ to 1350 cm⁻¹ was determined using a straight line connecting the intensity at 1050 cm⁻¹ as a background. Here, it is conceivable that the range from 1050 cm⁻¹ to 1350 cm⁻¹ is derived from the fluoride phosphor, the intensities at 3000 cm⁻¹ and 3800 cm⁻¹ or less are derived from H₂O, and the range from 3500 cm⁻¹ to 3800 cm⁻¹ is derived from Si—OH.

$$Z 1 = ( peak area of range from 3500 {cm}^{- 1} to 3800 {cm}^{- 1} ) / ( peak area of range from 1050 {cm}^{- 1} to 1350 {cm}^{- 1} or less ) \qquad ( P )$$

The results are shown in Table 3.

### (2) Amount of Silicon Dioxide

The composition of each of the produced light-emitting materials was analyzed by ICP emission spectrometry, the amount of silicon dioxide covering the fluoride phosphor was calculated from the difference in the analyzed Si concentration of the light-emitting material covered with silicon dioxide and produced in each of Examples 13 to 26 and the analyzed Si concentration of each fluoride phosphor before being covered with silicon dioxide in each of Examples 6 to 12, and thereby the content percentage (SiO₂ analysis value) of silicon dioxide in relation to the light-emitting material was determined. The results are shown in Tables 3 to 7.

### (3) X-ray Fluorescence Elemental Analysis: XRF Evaluation

The peak intensity of Kα rays of the F element of each of the light-emitting materials produced in Examples 9 and 16 was measured by X-ray fluorescence spectrometry (XRF) using an XRF device (product name: ZSX Primus II, available from Rigaku Corporation). The peak intensity ratio of the light-emitting material of Example 16 was calculated as a relative value with the peak intensity of the fluoride phosphor of Example 9 being 100. From the calculated peak intensity ratio, the average thickness of the silicon dioxide film in the light-emitting material of Example 16 was calculated using a database from The Center for X-Ray Optics (CXRO). The results are presented in Table 3.

### (4) Scanning Electron Microscope Observation

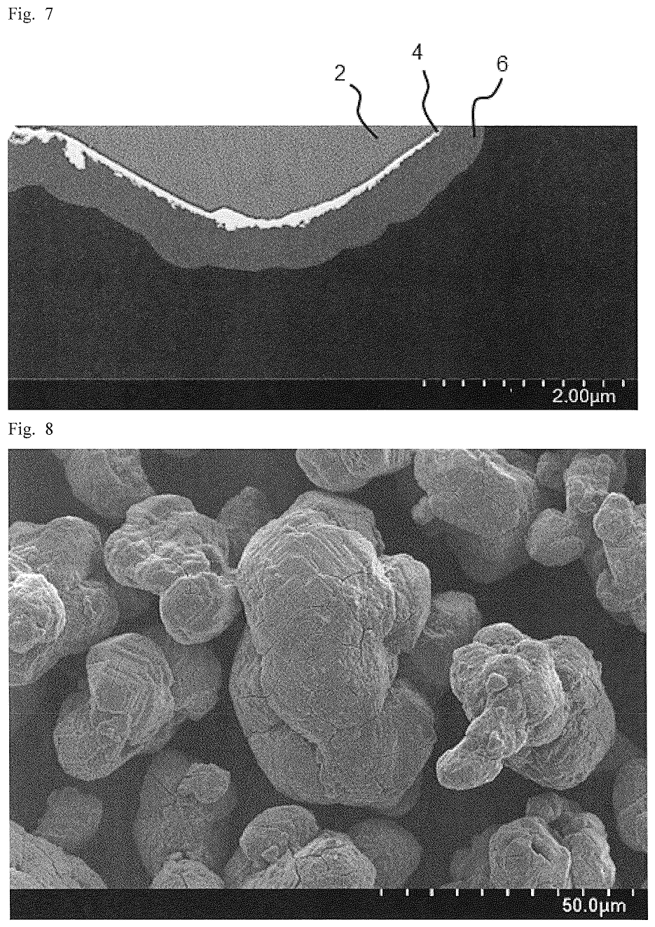

The produced light-emitting material of Example 17 was subjected to image observation using a scanning electron microscope (SEM). The SEM image is presented in FIG. 8. Furthermore, a cross section of the light-emitting material of Example 17 was observed using a scanning electron microscope (SEM), and the average thickness of the silicon dioxide film was measured by image analysis. Specifically, a plurality of light-emitting material particles was embedded in a resin, and a cross-sectional sample was prepared by ion milling such that the cross-section of the light-emitting material particles could be observed with a scanning electron microscope. The cross-sectional SEM image is shown in FIG. 7.

The thickness of the silicon dioxide film was measured at five locations for each light-emitting material particle in the cross-sectional SEM image taken, and the actually measured average thickness was calculated as an arithmetic average of the thicknesses at a total of 25 locations from five particles. Here, the thickness of the silicon dioxide film was defined as the thickness of the film visible on the SEM image including a portion where the film was cut obliquely in relation to the thickness direction. The results are shown in Table 4.

### (5) Total Carbon (TC)

The total carbon (TC) of each of the produced light-emitting materials of Examples 10, 18, and 22 to 26 and Comparative Example 4 was analyzed using a total organic carbon meter (product name: TOC-L, available from Shimadzu Corporation). The results are shown in Tables 4, 6 and 7.

### (6) Lanthanum Content Percentage

The lanthanum content percentage of each of the produced light-emitting materials of Examples 10 to 12, 17, 18, and 21 to 26 and Comparative Example 4 was analyzed by inductively coupled plasma atomic emission spectrometry (ICP-AES) to determine the content percentage (La analysis value) with respect to the light-emitting material. The results are shown in Tables 4 to 7.

### (7) Manganese Content

The manganese content percentage of each of the obtained light-emitting materials of Examples 11, 12, 15, and 19 to 26 and Comparative Examples 3 and 4 was analyzed by inductively coupled plasma atomic emission spectrometry (ICP-AES) to determine the content percentage (Mn analysis value) with respect to the light-emitting material. The results are shown in Tables 5 to 7.

### (8) Evaluation of Mass Change of Resin Composition

The influence of the light-emitting material on the change in mass of a resin composition containing a resin and the light-emitting material was evaluated as follows. A resin composition was prepared by mixing, into a silicon resin, 33 mass % of the light-emitting material in relation to the silicone resin. Approximately 1 g of the resultant resin composition was weighed on an aluminum foil and cured, after which the difference between the mass of the cured resin composition and the mass of the aluminum foil was calculated as an initial value. The resin composition cured on the aluminum foil was left to stand in a small oven (product name: LH-114 Constant Climate Cabinet, available from Espec Corp.) maintained at 200° C., and the mass after 100 hours, after 300 hours, after 500 hours, and after 1000 hours was measured. The mass retention rate (%) of the resin composition after the passage of each time was calculated with the initial mass value being 100%. A higher mass retention rate indicates a greater suppression of a reaction between the light-emitting material and the resin, meaning that the durability of the resin composition is excellent. A silicone resin selected from commercially available silicone resins was used for the evaluation. Specifically, the light-emitting materials of Examples 6 to 26 and Comparative Examples 2, 3, and 4 were evaluated using a dimethyl silicone resin (product name: KER-2936; refractive index of 1.41, hereinafter referred to as “dimethyl silicone resin 1”) available from Shin-Etsu Chemical Co., Ltd. The light-emitting materials of Examples 15 and 21 and Comparative Example 3 were also evaluated using a dimethyl silicone resin (trade name: OE-6351; refractive index of 1.41, hereinafter referred to as “dimethyl silicone resin 2”) available from Dow Corning Toray Co., Ltd., a phenyl silicone resin (trade name: OE-6630; refractive index of 1.53, hereinafter referred to as “phenyl silicone resin 1”) available from Dow Coning Toray Co., Ltd., and a phenyl silicone resin (refractive index of 1.50, hereinafter referred to as “phenyl silicone resin 2”) having a refractive index different from that of the phenyl silicone resin 1.

### (9) Durability Evaluation

The durability of each light-emitting material produced above was evaluated as follows. The internal quantum efficiency of each light-emitting material with respect to excitation light of 450 nm was measured using a quantum efficiency-measuring apparatus (product name: QE-2000, available from Otsuka Electronics Co., Ltd.), and the measured internal quantum efficiency was used as the initial characteristic. Subsequently, the light-emitting material was placed in a glass petri dish and allowed to stand for 100 hours in a small high-temperature, high-humidity tank (available from Espec Corp.) maintained at a temperature of 85° C. and a relative humidity of 85%. Subsequently, the internal quantum efficiency of each light-emitting material was measured by the same method, and the quantum efficiency maintenance rate (%) based on the initial characteristic being 100% was calculated. A higher quantum efficiency maintenance rate means better durability. The results are shown in Tables 3 to 7.

### Production Example 2 of Light-Emitting Device

The light-emitting materials of Examples 6 to 10 and 16 to 18 and Comparative Examples 2 to 4 were used as the first light-emitting material. A β-sialon phosphor having a composition represented by Si_{5.81}Al_{0.19}O_{0.19}N_{7.81}:Eu and having an emission peak near the 540 nm was used as the second light-emitting material. A resin composition was produced by mixing silicone resin with a phosphor 70 produced by blending the first light-emitting material 71 and the second light-emitting material72 such that as the chromaticity coordinates in the CIE1931 color system, x was around 0.280 and y was around 0.270. Subsequently, a molded body 40 having a recessed portion was prepared, a light-emitting device 10 made of a gallium nitride-based compound semiconductor and having an emission peak wavelength of 451 nm was disposed on the first lead 20 at the bottom of the recessed portion, and then electrodes of the light-emitting device 10 were connected to the first lead 20 and the second lead 30 by respective wires 60. Further, using a syringe, the resin composition was injected into the recessed portion of the molded body 40 so as to cover the light-emitting element 10, and the resin composition was cured to form a fluorescent member, and thereby a light-emitting device 2 was produced.

### Production Example 3 of Light-Emitting Device

The light-emitting materials of Examples 11, 12, 15, and 19 to 26 and Comparative Example 4 were used as the first light-emitting material. A rare-earth aluminate phosphor having a theoretical composition represented by Lu₃Al₅O₁₁:Ce and having an emission peak near 530 nm, a rare-earth aluminate phosphor having a theoretical composition represented by Y₃Al₅O₁₁:Ce and having an emission peak near 535 nm, and a nitride phosphor having a theoretical composition represented by (Ca, Sr)AlSiN₃:Eu and having an emission peak near 630 nm were used in combination as the second light-emitting material. A light-emitting device 3 was produced in the same manner as in Production Example 1 of the light-emitting device, with the exception that a resin composition was produced by mixing silicone resin with the phosphor 70 produced by blending the first light-emitting material71 and the second light-emitting material72 such that as the chromaticity coordinates in the CIE1931 color system, x was around 0.459 and y was around 0.411.

### Durability Evaluation 1

The light-emitting devices 2 produced using each of the light-emitting materials produced in Examples 9, 10, and 16 to 18 and Comparative Examples 3 and 4 and light-emitting devices 3 produced using each of the light-emitting materials produced in Examples 12 and 23 to 26 were subjected to a durability test 1 by being stored in an environmental tester at 85° C. and 85% RH for 500 hours. A luminous flux maintenance rate 1(%) of each light-emitting device after the durability test 1 was determined based on the luminous flux of the light-emitting device before the durability test 1 being 100%. A higher luminous flux maintenance rate 1 indicates more excellent durability against high temperature and high humidity conditions. The results are shown in Tables 3, 4 and 7.

### Durability Evaluation 2

The light-emitting devices 3 produced using each of the light-emitting materials produced in Examples 11, 12, 15, and 19 to 26 and Comparative Example 4 were subjected to a durability test 2 by being driven at a current value of 150 mA for 1000 hours in a non-humidified environmental tester at a temperature of 85° C. A luminous flux maintenance rate 2(%) of each light-emitting device after the durability test 2 was determined based on the luminous flux of the light-emitting device before the durability test 2 being 100%. A higher luminous flux maintenance rate 2 indicates more excellent durability against high heat. The results are shown in Tables 6 and 7.

### Durability Test 3

Each of the light-emitting devices 2 produced using each of the light-emitting materials produced in Examples 6 to 8 and Comparative Examples 2 and 3 was placed in a non-humidified environmental tester at a temperature of 85° C., and the x value of the color coordinates was measured when the device was driven at a current value of 150 mA for 100 hours and 500 hours. The color coordinate x at 100 hours was defined as an initial value, and the amount of change in x at 500 hours was defined as [symbol] x. A smaller [symbol] x indicates more excellent color stability against high heat. The results are shown in Table 3.

TABLE 3

| | Light-emitting material | | | | | | | | | | | Light-emitting device 2 | |
|---|---|---|---|---|---|---|---|---|---|---|---|---|---|
| | | IR peak | SiO₂ | SiO₂ | Peak | Average | Quantum | | | | | Luminous | Chromaticity |
| | Phosphor | area | charged | analysis | inten- | thick- | efficiency | | | | | flux | coordinate x |
| | compo- | ratio | amount | value | sity | ness | maintenance | Mass retention rate (%) | | | | maintenance | change |
| | sition | Z1 | (mass %) | (mass %) | ratio | (μm) | rate (%) | 100 h | 300 h | 500 h | 1000 h | rate 1 (%) | amount Δx |
| Comparative | KSF | 0.0048 | 0 | — | — | — | — | 84 | 35 | 32 | — | — | −0.0041 |
| Example 2 | | | | | | | | | | | | | |
| Comparative | | 0.0006 | 0 | — | — | — | 79.2 | 92 | 36 | 32 | 31 | 85 | −0.0023 |
| Example 3 | | | | | | | | | | | | | |
| Example 6 | KSAF | 0.0003 | 0 | — | — | — | — | 84 | 38 | 34 | — | — | −0.0010 |
| Example 7 | | — | 0 | — | — | — | — | 95 | 50 | 43 | — | — | −0.0020 |
| Example 8 | | — | 0 | — | — | — | — | 84 | 36 | 33 | 31 | — | −0.0012 |
| Example 9 | | — | 0 | — | 100 | 0 | 68.9 | 79 | 37 | 34 | 31 | 88 | — |
| Example 13 | | — | 10 | 9.0 | — | — | — | 99 | 97 | 96 | — | — | — |
| Example 14 | | — | 10 | 8.8 | — | — | — | 99 | 97 | 96 | — | — | — |
| Example 15 | | — | 10 | 9.0 | — | — | — | 100 | 97 | 96 | 92 | — | — |
| Example 16 | | — | 10 | 9.1 | 42 | 0.45 | 84.9 | 100 | 97 | 95 | 91 | 91 | — |

TABLE 4

| | | | | | | | | | | | | Light- |
|---|---|---|---|---|---|---|---|---|---|---|---|---|
| | | | | | | | | | | | | emitting |
| | Light-emitting material | | | | | | | | | | | device 2 |
| | | SiO₂ | SiO₂ | La | TC | Measured | Quantum | | | | | Luminous |
| | Phosphor | charged | analysis | analysis | analysis | average | efficiency | | | | | flux |
| | compo- | amount | value | value | value | thickness | maintenance | Mass retention rate (%) | | | | maintenance |
| | sition | (mass %) | (mass %) | (mass %) | (ppm) | (μm) | rate (%) | 100 h | 300 h | 500 h | 1000 h | rate 1 (%) |
| Comparative | KSF | 0 | — | 1.36 | 50 | — | 91.7 | 99 | 69 | 49 | 41 | 87 |
| Example 4 | | | | | | | | | | | | |
| Example 10 | KSAF | 0 | — | 1.02 | 20 | — | 90.3 | 99 | 64 | 45 | 38 | 87 |
| Example 17 | | 10 | 9.1 | 0.93 | — | 0.44 | 92.6 | 100 | 97 | 95 | 92 | 91 |
| Example 18 | | 10 | 8.7 | 0.91 | 170 | — | 93.7 | 99 | 97 | 94 | 90 | 91 |

TABLE 5

| | Phosphor | | | | | | | | | |
|---|---|---|---|---|---|---|---|---|---|---|
| | | SiO₂ | SiO₂ | Mn | La | Quantum | | | | |
| | Phosphor | charged | analysis | analysis | analysis | efficiency | | | | |
| | compo- | amount | value | value | value | maintenance | | Mass retention rate (%) | | |
| | sition | (mass %) | (mass %) | (mass %) | (mass %) | rate (%) | Resin | 100 h | 300 h | 500 h |
| Comparative | KSF | 0 | — | 1.50 | 0 | 79.2 | Dimethyl silicone resin 1 | 92 | 36 | 32 |
| Example 3 | | | | | | | Dimethyl silicone resin 2 | 41 | 38 | 37 |
| | | | | | | | Phenyl silicone resin 1 | 88 | 79 | 76 |
| | | | | | | | Phenyl silicone resin 2 | 92 | 88 | 86 |
| Example 15 | KSAF | 10 | 9.0 | 0.92 | 0 | 93.5 | Dimethyl silicone resin 1 | 100 | 96 | 95 |
| | | | | | | | Dimethyl silicone resin 2 | 97 | 86 | 74 |
| | | | | | | | Phenyl silicone resin 1 | 98 | 95 | 93 |
| | | | | | | | Phenyl silicone resin 2 | 100 | 96 | 94 |
| Example 21 | | | 8.6 | 0.91 | 1.03 | 95.9 | Dimethyl silicone resin 1 | 100 | 97 | 96 |
| | | | | | | | Dimethyl silicone resin 2 | 98 | 92 | 85 |
| | | | | | | | Phenyl silicone resin 1 | 98 | 96 | 95 |
| | | | | | | | Phenyl silicone resin 2 | 97 | 96 | 95 |

TABLE 6

| | | | | | | | | | | | | Light- |
|---|---|---|---|---|---|---|---|---|---|---|---|---|
| | | | | | | | | | | | | emitting |
| | Light-emitting material | | | | | | | | | | | device 3 |
| | | SiO₂ | SiO₂ | Mn | La | TC | Quantum | | | | | Luminous |
| | Phosphor | charged | analysis | analysis | analysis | analysis | efficiency | | | | | flux |
| | compo- | amount | value | value | value | value | maintenance | | Mass retention rate (%) | | | maintenance |
| | sition | (mass %) | (mass %) | (mass %) | (mass %) | (ppm) | rate (%) | Resin | 100 h | 300 h | 1000 h | rate 2 (%) |
| Comparative | KSF | 0 | — | 1.50 | 1.36 | 50 | 91.7 | Dimethyl | 99 | 69 | 41 | 97.5 |
| Example 4 | | | | | | | | silicone | | | | |
| Example 11 | KSAF | 0 | — | 1.00 | 1.14 | — | 93.9 | resin 1 | 98 | 78 | 45 | 96.3 |
| Example 15 | | 10 | 9.0 | 0.92 | — | — | 93.5 | | 100 | 97 | 92 | 96.4 |
| Example 19 | | 6 | 5.9 | 0.94 | — | — | 94.9 | | 100 | 97 | 90 | 99.0 |
| Example 20 | | 3 | 3.0 | 0.95 | — | — | 96.8 | | 100 | 97 | 80 | 98.7 |
| Example 21 | | 10 | 8.6 | 0.91 | 1.03 | — | 95.9 | | 100 | 97 | 93 | 97.7 |
| Example 22 | | 10 | 8.7 | 0.92 | 1.02 | 260 | 98.2 | | 100 | 97 | 92 | 98.4 |

TABLE 7

| | Light-emitting material | | | | | | | | | Light-emitting Device 3 | |
|---|---|---|---|---|---|---|---|---|---|---|---|
| | | SiO₂ | SiO₂ | Mn | La | TC | Quantum | | Mass | Luminous | Luminous |
| | Phosphor | charged | analysis | analysis | analysis | analysis | efficiency | | retention | flux | flux |
| | compo- | amount | value | value | value | value | maintenance | | rate (%) | maintenance | maintenance |
| | sition | (mass %) | (mass %) | (mass %) | (mass %) | (ppm) | rate (%) | Resin | 1000 h | rate 1 (%) | rate 2 (%) |
| Example 12 | KSAF | 0 | — | 1.20 | 1.05 | — | 93.3 | Dimethyl | 42 | 98.9 | 95.8 |
| Example 23 | | 6 | 5.8 | 1.13 | 0.94 | 560 | 97.1 | silicone | 92 | 99.5 | 96.3 |
| Example 24 | | | 5.8 | 1.13 | 0.96 | 400 | 97.0 | resin 1 | 92 | 99.9 | 96.7 |
| Example 25 | | | 6.0 | 1.13 | 0.97 | 1600 | 96.2 | | 91 | 97.3 | 97.3 |
| Example 26 | | | 5.8 | 1.13 | 0.96 | 430 | 97.9 | | 92 | 100.3 | 96.8 |

The SiO₂ analytical values of the light-emitting materials of Examples 15, 19 and 20 increased as the charging amount of SiO₂ was increased. In the light-emitting material of Example 16, the peak intensity ratio of Kα rays of the F element measured by XRF was reduced to 42 in relation to the peak intensity of 100 of the light-emitting material of Example 9. From this, it is conceivable that the Kα rays of the F element are absorbed by the SiO₂ film, and it is conceivable that SiO₂ covers the surface of each fluoride particle as a film. Further, the film thickness of the SiO₂ film was calculated from the absorption rate and found to be 0.45 μm.

In comparison with the light-emitting material having the second theoretical composition (KSF) of Comparative Example 2, the light-emitting material (KSAF) having the first theoretical composition of Example 6 had a smaller FT-IR peak area ratio (Z1). In comparison with the light-emitting devices 2 that used the light-emitting materials (KSF) of Comparative Examples 2 and 3, the light-emitting devices 2 that used the light-emitting materials (KSAF) of Examples 6 to 8 had a smaller Ax. From this fact, it is clear that KSAF has fewer —OH groups on the particle surface even without the second heat treatment, and is superior to KSF in terms of the color stability of the light-emitting device. That is, KSAF exhibits excellent color stability in the first heat-treated material, the second heat-treated material, and the third heat-treated material. In comparison to the resin compositions containing the light-emitting materials of Comparative Examples 2 and 3 and Examples 6 to 9, the resin compositions containing the light-emitting materials having the SiO₂ film of Examples 13 to 16 exhibited higher mass retention rates and better durability of the resin compositions. Regarding durability of the resin composition, it is clear that in comparison to Example 20 in which the average thickness of the SiO₂ film was thin, in Examples 19 and 15 in which the average thickness of the SiO₂ film was thick, the mass retention rate of the resin composition after 1000 hours was improved, and the durability of the resin composition was further enhanced.

The luminous flux maintenance rate 1 of the light-emitting device 2 in which the light-emitting material of Example 16 was used was higher than that of the light-emitting device 2 in which the light-emitting material of Comparative Example 3 was used, and the light-emitting device 2 was more excellent in durability. From this, it is clear that a light-emitting device that uses a fluoride phosphor coated with an SiO₂ film exhibits higher durability.

FIG. 7 presents an SEM image taken when the light-emitting material produced in Example 17 was observed using a scanning electron microscope. From FIG. 7, it is clear that the silicon dioxide covering the fluoride particles having the KSAF theoretical composition is in the form of a continuous film and not in the form of particles.

FIG. 8 presents an image taken when a cross section of the light-emitting material produced in Example 17 was observed using a scanning electron microscope. In FIG. 8, the gray portion corresponds to fluoride particles 2, the white portion corresponds to lanthanum phosphate 4, and the dark gray portion corresponds to the silicon dioxide 6. From this, it is clear that the lanthanum phosphate 4 is adhered to the fluoride particles 2 and is further covered with the silicon dioxide 6.

TC analysis values of the light-emitting materials of Examples 18 and 22 to 26 were higher than that of the light-emitting material of Comparative Example 4, and the presence of carbon was confirmed. Since this carbon is considered to be derived from the silane coupling agent, it is conceivable that a component derived from the silane coupling agent is adhered to the surface of the fluoride phosphor by subjecting the fluoride phosphor covered with SiO₂ to the silane coupling treatment.

In comparison to the light-emitting material of Example 10 in which lanthanum phosphate was adhered to the fluoride phosphor, the light-emitting material of Example 17 covered with the SiO₂ film had a higher quantum efficiency maintenance rate in the durability evaluation and a higher mass retention rate of the resin composition, and was more excellent in durability of the light-emitting material and the resin composition. Regarding durability, it is clear that in comparison to Example 17, a higher quantum efficiency maintenance rate and further improved durability were exhibited by Example 18, which was subjected to the silane coupling treatment. The quantum efficiency maintenance rate of Example 17 to which lanthanum phosphate was adhered was higher than that of Example 16 to which lanthanum phosphate was not adhered, and a higher effect was achieved by covering, with SiO₂, the surface of the phosphor to which lanthanum phosphate was adhered. That is, even with the fluoride phosphor to which lanthanum phosphate was adhered, an effect of improving durability was achieved by covering the fluoride phosphor with an SiO₂ film.

In comparison with the light-emitting device 2 in which the light-emitting material of Example 10 was used, further improvements in durability were observed in the light-emitting devices 2 that used the light-emitting materials of Examples 17 and 18, and a durability improvement effect was achieved by covering the fluoride particles with an SiO₂ film, even with the fluoride particles to which lanthanum phosphate was attached.

When the sedimentation state of the phosphor was confined by observing the cross section of the light-emitting device, the light-emitting material was most sedimented in the light-emitting device 2 in which the light-emitting material of Example 18 subjected to the silane coupling treatment. In this case, it is conceivable that the affinity with the resin was improved by the silane coupling treatment, and as a result, the light-emitting material was more easily sedimented.

The light-emitting materials of Examples 15 and 21 had higher quantum efficiency maintenance rates than the light-emitting material of Comparative Example 3. In addition, in comparison to the light-emitting material of Comparative Example 3, the light-emitting materials of Examples 15 and 21 exhibited higher mass retention rates of the resin composition and better durability of the resin composition. With the phenyl silicone resins 1 and 2, the mass retention rate was high even with the fluoride particles of Comparative Example 3, but in Examples 15 and 21, the mass retention rate was even higher. In the cases in which the dimethyl silicone resins 1 and 2 were used, the mass retention rate of the light-emitting material of Comparative Example 3 was significantly reduced, but the mass retention rates of Examples 15 and 21 were high. In particular, the mass retention rate of Example 21 was higher, and a higher effect was achieved by covering, with the SiO₂ film, the surface of the phosphor to which lanthanum phosphate was adhered. With each of the resins, in comparison to the fluoride particles of Example 3 having KSF as the composition, the durability of the resin composition was more excellent in Example 15 in which the fluoride particles having KSAF as the composition were covered with the SiO₂ film and in Example 21 in which the surface of the phosphor having lanthanum phosphate adhered thereto was covered with the SiO₂ film.

The light-emitting materials of Examples 15 and 19 to 22 had higher quantum efficiency maintenance rates than the light-emitting material of Comparative Example 4. The mass retention rates of the resin compositions were also higher, and the durability of the resin compositions was excellent. The light-emitting devices 3 in which the light-emitting materials of Examples 15 and 19 to 22 were used exhibited higher luminous flux maintenance rates 2 and more excellent durability than the light-emitting device 3 in which the light-emitting material of Example 11 was used. In the light-emitting devices 3 in which the light-emitting materials of Examples 21 and 22 were used, a light-emitting material in which the surface of the phosphor to which lanthanum phosphate was adhered was covered with SiO₂ was used, and these light-emitting devices 3 exhibited more excellent durability than the light-emitting device in which the light-emitting material of Example 15 was used. This result seems to be due to the lanthanum phosphate improving the adhesiveness of the silica coating, resulting in a suppression of peeling of the coating layer, and the like. Furthermore, with the light-emitting device 3 in which the light-emitting material of Example 22 is used, it is conceivable that the affinity with the resin was improved by the silane coupling treatment, and thereby the phosphor was easily sedimented, and adherence with the resin was also improved, and as a result, an even higher effect was achieved. The light-emitting devices that used the light-emitting materials of Examples 19 and 20 in which the SiO₂ concentration was reduced exhibited more excellent durability than the light-emitting device that used the fluoride phosphor of Example 15. It is conceivable that the reason for this is that the reduction in the SiO₂ concentration resulted in a suppression of cracking of the SiO₂ film, which also resulted in a suppression of contact with the external environment at locations of cracking. The light-emitting devices 3 that used the light-emitting materials of Examples 19 and 20 in which the fluoride particles having the KSAF composition were covered with the SiO₂ film, and the light-emitting devices 3 that used the light-emitting materials of Examples 211 and 22 in which the fluoride particles having the KSAF composition and having lanthanum phosphate adhered thereto were covered with the SiO₂ film exhibited more excellent durability than the light-emitting device that used the fluoride particles of Comparative Example 4 having the KSF composition and having lanthanum phosphate adhered thereto.

The light-emitting materials of Examples 23 to 26 exhibited higher quantum efficiency maintenance rates than that of the light-emitting material of Example 12. The mass retention rates of these resin compositions were also further increased, and the durability as a powder was excellent, and it is conceivable that the affinity with the resin was improved by the silane coupling treatment. In the durability evaluation 1, the light-emitting devices that used the light-emitting materials of Examples 23, 24, and 26 exhibited higher luminous flux maintenance rates 1 than the light-emitting device that used the light-emitting material of Example 12. Further, in the durability evaluation 2, the light-emitting devices that used the light-emitting materials of Examples 23 to 26 exhibited higher luminous flux maintenance rates 2 than the light-emitting device that used the light-emitting material of Example 12. The primary cause for this can be considered to be as follows, for example. In the silane coupling agent, a methoxy group or an ethoxy group is hydrolyzed to form a hydrogen bond with an —OH group on the surface of the phosphor, and is chemically bonded by heating. Therefore, it is difficult for the silane coupling agent to bind to a fluoride particle having the KSAF composition with fewer —OH groups on the surface. On the other hand, it is conceivable that a large number of —OH groups are present on the surface of the fluoride phosphor in which the fluoride particles are covered with SiO₂, and thus the silane coupling agent is easily bonded, and the affinity with the resin is further improved, and thus the effect as described above is achieved. In particular, in the light-emitting materials of Examples 23 to 26, the surface of the phosphor to which lanthanum phosphate was adhered was covered with SiO₂. It is conceivable that the lanthanum phosphate further improved the adhesiveness of the SiO₂ film and further suppressed cracking, peeling, and the like of the coating layer, and thereby uniform bonding of the silane coupling agent was facilitated, and affinity with the resin was improved.

The fluoride phosphor and the light-emitting material produced by the production method of the present disclosure can be used in a light-emitting device in which a light-emitting diode is used as an excitation light source, and for example, can be suitably used in a light source for illumination, a light source for application in an LED display or liquid crystal backlight, a traffic signal, an illuminated switch, various sensors, various indicators, and a compact strobe.

The disclosures of JP 2021-091754 (filed on May 31, 2021), JP 2021-130074 (filed on Aug. 6, 2021), JP 2021-141629 (filed on Aug. 31, 2021), and JP 2022-083514 (filed on May 23, 2022) are incorporated herein by reference in their entirety. All publications, patent applications, and technical standards described in the present specification are incorporated herein by reference to the same extent as a case in which the incorporation by reference of each individual publication, patent application, and technical standard is specifically and individually indicated to be incorporated by reference.

1. A light-emitting material comprising a fluoride phosphor having a first composition comprising: an alkali metal including K; Si; Al; Mn; and F such that when a total number of moles of the alkali metal is 2, a total number of moles of Si, Al, and Mn is in a range from 0.9 to 1.1, a number of moles of Al is in a range from greater than 0 to 0.1, a number of moles of Mn is in a range from greater than 0 to 0.2, and a number of moles of F is in a range from 5.5 to less than 6.0, and
the fluoride phosphor having, as a crystal structure, a cubic system crystal structure and having a lattice constant of 0.8138 nm or larger.

2. A light-emitting material comprising a fluoride phosphor having a first composition comprising: an alkali metal including K; Si; Al; Mn; and F such that when a total number of moles of the alkali metal is 2, a total number of moles of Si, Al, and Mn is in a range from 0.9 to 1.1, a number of moles of Al is in a range from greater than 0 to 0.1, a number of moles of Mn is in a range from greater than 0 to 0.2, and a number of moles of F is in a range from 5.5 to less than 6.0, and
in an infrared absorption spectrum, the fluoride phosphor has an absorption peak in a wavenumber range from 590 cm⁻¹ to 610 cm⁻¹.

3. The light-emitting material according to claim 1, wherein the fluoride phosphor has a composition represented by Formula (I): 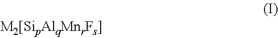
where M represents an alkali metal and includes at least K, and p, q, r, and s satisfy 0.9≤p+q+r≤1.1, 0<q≤0.1, 0<r≤0.2, and 5.5≤s≤6.0.

4. The light-emitting material according to claim 1, wherein in the first composition, the total number of moles of Si, Al, and Mn is 1 when the total number of moles of the alkali metal is 2.

5. The light-emitting material according to claim 1, wherein the number of moles of Al in the first composition is in a range from greater than 0 to 0.06.

6. The light-emitting material according to claim 1, further comprising an oxide disposed on at least a portion of a surface of the fluoride phosphor, wherein
the oxide contains at least one element selected from the group consisting of Si, Al, Ti, Zr, Sn, and Zn, and a content percentage of the oxide is in a range from 2 mass % to 30 mass % in relation to the light-emitting material.

7. The light-emitting material according to claim 6, wherein a rare earth phosphate containing at least one rare earth element selected from the group consisting of La, Ce, Dy and Gd is disposed on a surface of the fluoride phosphor, and the oxide is disposed on at least a portion of the surface of the fluoride phosphor with the rare earth phosphate interposed therebetween.

8. The light-emitting material according to claim 1, further comprising a rare earth phosphate disposed on at least a portion of the surface of the fluoride phosphor, wherein
the rare earth phosphate contains at least one rare earth element selected from the group consisting of La, Ce, Dy and Gd.

9. A method for producing a light-emitting material, the method comprising:
preparing first fluoride particles having a second composition comprising an alkali metal including K, Si, Mn, and F such that when a total number of moles of the alkali metal is 2, a total number of moles of Si and Mn is in a range from 0.9 to 1.1, a number of moles of Mn is in a range from greater than 0 to 0.2, and a number of moles of F is in a range from 5.5 to less than 6.0;
preparing second fluoride particles having a third composition comprising an alkali metal including K, Al, and F such that when a number of moles of Al is 1, a total number of moles of the alkali metal is in a range from 2 to 3, and a number of moles of F is in a range from 5 to 6; and
subjecting a mixture of the first fluoride particles and the second fluoride particles to a first heat treatment in an inert gas atmosphere at a temperature in a range from 600° C. to 780° C. to produce a first heat-treated material.

10. The method for producing a light-emitting material according to claim 9, wherein in the preparing of the first fluoride particles, the total number of moles of Si and Mn in the second composition is 1 when the total number of moles of the alkali metal is 2.

11. The method for producing a light-emitting material according to claim 9, further comprising causing the first heat-treated material to contact a first liquid medium.

12. The method for producing a light-emitting material according to claim 9, further comprising subjecting the first heat-treated material to a second heat treatment at a temperature in a range from 400° C. to 600° C. to produce a second heat-treated material.

13. The method for producing a light-emitting material according to claim 12, further comprising causing the second heat-treated material and a metal alkoxide containing at least one element selected from the group consisting of Si, Al, Ti, Zr, Sn, and Zn to come into contact in a liquid medium to thereby dispose an oxide derived from the metal alkoxide on at least a portion of a surface of the fluoride phosphor at an amount in a range from 2 mass % to 30 mass % relative to the light-emitting material.

14. The method for producing a light-emitting material according to claim 12, further comprising causing the second heat-treated material, rare earth ions including at least one type selected from the group consisting of La, Ce, Dy, and Gd, and phosphate ions to come into contact in a liquid medium to produce a second heat-treated material having a rare earth phosphate disposed on at least a portion of a surface of the second heat-treated material.

15. The method for producing a light-emitting material according to claim 14, further comprising causing the second heat-treated material on which the rare earth phosphate is disposed and a metal alkoxide containing at least one element selected from the group consisting of Si, Al, Ti, Zr, Sn, and Zn to come into contact in a liquid medium to thereby dispose, at an amount in a range from 2 mass % to 30 mass % in relation to the light-emitting material, an oxide derived from the metal alkoxide on at least a portion of a surface of the second heat-treated material on which the rare earth phosphate is attached.

16. The method for producing a light-emitting material according to claim 9, further comprising subjecting the first heat-treated material to a pressurizing treatment and a heating treatment together with a second liquid medium to produce a third heat-treated material.

17. The method for producing a light-emitting material according to claim 16, wherein the heating treatment is carried out at a temperature of 100° C. or higher.

18. The method for producing a light-emitting material according to claim 16, wherein the pressurizing treatment is carried out at 1.6 MPa or higher.

19. The method for producing a light-emitting material according to claim 16, wherein the second liquid medium contains water.

20. The method for producing a light-emitting material according to claim 16, wherein the second liquid medium contains potassium.

21. The method for producing a light-emitting material according to claim 16, further comprising causing the third heat-treated material and a metal alkoxide containing at least one element selected from the group consisting of Si, Al, Ti, Zr, Sn, and Zn to come into contact in a liquid medium to thereby dispose an oxide derived from the metal alkoxide on at least a portion of a surface of the fluoride phosphor at an amount in a range from 2 mass % to 30 mass % relative to the light-emitting material.

22. The method for producing a light-emitting material according to claim 16, further comprising causing the third heat-treated material, rare earth ions including at least one type selected from the group consisting of La, Ce, Dy, and Gd, and phosphate ions to come into contact in a liquid medium to produce a second heat-treated material having a rare earth phosphate disposed on at least a portion of a surface of the second heat-treated material.

23. The method for producing a light-emitting material according to claim 22, further comprising causing the third heat-treated material on which the rare earth phosphate is disposed and a metal alkoxide containing at least one element selected from the group consisting of Si, Al, Ti, Zr, Sn, and Zn to come into contact in a liquid medium to thereby dispose, at an amount in a range from 2 mass % to 30 mass % in relation to the light-emitting material, an oxide derived from the metal alkoxide on at least a portion of a surface of the second heat-treated material on which the rare earth phosphate is attached.
